(19) United States
(12) Patent Application Publication
(10) Pub. No.: US 2021/0380616 A1
(43) Pub. Date: Dec. 9, 2021

(54) TUNGSTEN (VI) COMPOUNDS WITH THERMALLY ACTIVATED DELAYED FLUORESCENCE OR PHOSPHORESCENCE FOR ORGANIC LIGHT-EMITTING DEVICES

(71) Applicant: THE UNIVERSITY OF HONG KONG, Hong Kong (CN)

(72) Inventors: Chi Ming CHE, Hong Kong (CN); Kaai Tung CHAN, Hong Kong (CN)

(21) Appl. No.: 17/053,426

(22) PCT Filed: May 31, 2019
(86) PCT No.: PCT/CN2019/089591

§ 371 Date: Nov. 6, 2020

Related U.S. Application Data
(60) Provisional application No. 62/679,280, filed on Jun. 1, 2018.

(51) Int. Cl. C07F 11/00; C09K 11/06; H01L 51/00

(52) U.S. Cl. CPC C07F 11/005; C09K 11/06; H01L 51/5016; C09K 2211/183; H01L 51/0084

(57) ABSTRACT

A strongly emissive OLED emitter which is a tungsten (VI) complex showing thermally activated delay fluorescence or phosphorescence behavior and a di-hydroxy Schiff base tetradentate ligand for the preparation of the OLED emitter are provided. The synthesis of the tetradentate ligand and tungsten (VI) complex is illustrated. The OLED emitter can be used to fabricate OLED devices.

### BACKGROUND OF INVENTION

Organic Light-Emitting Diodes (OLEDs) represent a growing technology that competes with ordinary Light-Emitting Diodes (LEDs) for a light-display technology due to their characteristics of high color-purity, energy-efficiency, and applicability toward fabrication of flexible displays. The cost of an OLED device is mainly dependent on the cost of the metal emitters, which includes the cost incurred during synthesis of the target compounds and more importantly, the cost of the corresponding metal salts. Essentially, all available OLEDs emitters are based on expensive rare-earth metals like iridium, platinum and, more recently, gold. Discovering alternative inexpensive metal complexes for fabrication of OLED emitters is important for the market penetration of OLEDs. There has been growing research for alternative emitters based on less expensive metals, such as copper.

Tungsten(VI) complexes with a 5d⁰ electronic configuration, are exempt from the effect of the non-radiative d-d state. This feature, combined with the heavy atom effect brought about by the tungsten metal center (ξw˜2400 cm⁻¹) that facilitates intersystem crossing and phosphorescence, has the potential to demonstrate significant phosphorescence in complexes having a rigid ligand framework. Tungsten complexes have been shown to constitute a class of potential OLED emitters, but improvements in terms of PLQY, EQE and efficiency-roll off of OLED devices are required. The potential to significantly boost PLQY by incorporating a combination of suitable spacer and donor units to the ligand framework of tungsten compounds is a possibility. In some cases, tungsten compounds of this nature, having thermally activated delayed fluorescence (TADF) properties, have a high potential to realize efficient OLED emitters. In this manner, low-cost strongly luminescent tungsten(VI) based emitters, particularly those demonstrating TADF property, have the potential to exhibit competitive with other candidates in the OLED industry, allowing their widespread use as tungsten(VI) as OLED emitters.

### BRIEF SUMMARY

An embodiment of the invention is directed to tungsten(VI) emitters of Structure I, below. These complexes show high photoluminescent quantum yield with thermally activated delayed fluorescence or phosphorescence properties. Other embodiments of the invention are directed to methods of preparing tungsten(VI) emitters of Structure I and to use the tungsten(VI)-based compounds in organic light-emitting diode (OLED) applications. The tungsten(VI)-based compounds of Structure I have the structure:

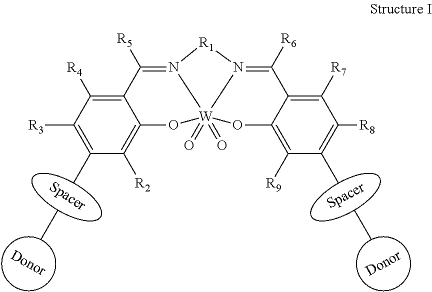

where: W is a tungsten center with an oxidation state of VI; R₁ is a connector between imine (C═N) units which, can be a single bond or a bridge comprising a plurality of atoms and bonds, including, but not limited to, —O—, —S—, alkylene (e.g., having 1 to 6 carbon atoms), cycloalkylene (e.g., having 3 to 12 carbon atoms), alkenylene (e.g., having 2 to 8 carbon atoms), arylene (e.g., having 6 to 10 carbon atoms), sulfonyl, carbonyl, —CH(OH)—, —C(═O)O—, —O—C(═O)—, or heterocyclene group (e.g., having 5 to 8 ring atoms), or a combination of two or more of such groups; optionally, spacers, each of which connecting a donor with the W(VI) cis-dioxo Schiff base core by a single bond, an unsubstituted or substituted C₆-C₁₀ arylene or C₆-C₁₀ heteroarylene; and donors that are electron rich unsubstituted or substituted diaryl amine or an unsubstituted or substituted nitrogen heterocyclic aromatic. The spacer can be absent with the donor bonded directly to the W(VI) cis-dioxo Schiff base core by a single bond. In the W(VI) cis-dioxo Schiff base core, R₂-R₉ are independently hydrogen, halogen, hydroxyl, unsubstituted alkyl, substituted alkyl, cycloalkyl, unsubstituted aryl, substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, or an alkoxycarbonyl group. Independently, any pair of adjacent R groups separated by three or four bonds can form 5-8 member rings, such as cycloalkyl, aryl, heterocycle, or heteroaryl ring.

### BRIEF DESCRIPTION OF DRAWINGS

FIG. 1 shows a multistep reaction scheme for the preparation of exemplary Emitters, according to an embodiment of the invention.

FIG. 2 shows a perspective view of the crystal structure of Emitter 105, according to an embodiment of the invention.

FIG. 3 shows the photoluminescence spectra of Emitter 105 in various solvents at 298 K, according to an embodiment of the invention.

FIG. 4 shows PL spectra of a thin film of Emitter 105 at 298 K and 77 K, according to an embodiment of the invention.

FIG. 5 shows a perspective view of the crystal structure of Emitter 101, according to an embodiment of the invention.

FIG. 6 shows the photoluminescence spectra of Emitter 101 in various solvents at 298 K, according to an embodiment of the invention.

FIG. 7 shows the photoluminescence spectra of Emitter 102 in various solvents at 298 K, according to an embodiment of the invention.

FIG. 8 shows the photoluminescence spectra of Emitter 103 in various solvents at 298 K, according to an embodiment of the invention.

FIG. 9 shows emission lifetime measurements for Emitter 105 over a 77K-298K temperature range, according to an embodiment of the invention.

FIG. 10 shows normalized EL spectra of solution-processed devices fabricated with Emitters 101, 102 and 105, according to an embodiment of the invention.

FIG. 11 shows EQE-luminance characteristics of solution-processed devices fabricated with Emitters 101, 102 and 105, according to an embodiment of the invention.

FIG. 12 shows Luminance-voltage characteristics of solution-processed devices fabricated with Emitters 101, 102 and 105, according to an embodiment of the invention.

FIG. 13 shows Power-efficiency-luminance characteristics of solution-processed devices fabricated with Emitters 101, 102 and 105, according to an embodiment of the invention.

### DETAILED DISCLOSURE

To facilitate the understanding of this disclosure, a number of terms, abbreviations or other shorthand as used herein and are defined below. Any term, abbreviation or shorthand not defined is understood to have the ordinary meaning used by a skilled artisan contemporaneous with the submission of this application.

“Amino” refers to a primary, secondary, or tertiary amine which may be optionally substituted. Specifically included are secondary or tertiary amine nitrogen atoms which are members of a heterocyclic ring. Also specifically included, for example, are secondary or tertiary amino groups substituted by an acyl moiety. Some non-limiting examples of an amino group include —NR′R″ wherein each of R′ and R″ is independently H, alkyl, aryl, aralkyl, alkaryl, cycloalkyl, acyl, heteroalkyl, heteroaryl or heterocycyl.

“Alkyl” refers to a fully saturated acyclic monovalent radical containing carbon and hydrogen, and which may be branched or a straight chain. Examples of alkyl groups include, but are not limited to, alkyl having 1-20, 1-10 or 1-6 carbon atoms, methyl, ethyl, n-propyl, isopropyl, n-butyl, t-butyl, n-heptyl, n-hexyl, n-octyl, and n-decyl.

“Alkylene” refers to the above mentioned alkyl groups, having a pair of bonds bonding the alkyl group between two other entities in the complex.

“Alkenyl” refers to a radical of a straight-chain or branched hydrocarbon group having from 2-20, 2-10, or 2-6 carbon atoms, one or more carbon-carbon double bonds (e.g., 1, 2, or 3 carbon-carbon double bonds). The one or more carbon-carbon double bonds can be internal (such as in 2-butenyl) or terminal (such as in 1-butenyl). In some embodiments, C₂₋₄ alkenyl is particularly preferred. Examples of alkenyl groups include, but are not limited to, ethenyl (C₂), 1-propenyl (C₃), 2-propenyl (C₃), 1-propen-2-yl (C₃), 1-butenyl (C₄), 2-butenyl (C₄), butadienyl (C₄), pentenyl (C₅), pentadienyl (C₅), hexenyl (C₆), and the like.

“Alkenylene” refers to the above mentioned alkenyl groups, having a pair of bonds bonding the alkenyl group between two other entities in the complex.

“Alkynyl” refers to a radical of a straight-chain or branched hydrocarbon group having from 2-20, 2-10, or 2-6 carbon atoms, one or more carbon-carbon triple bonds (e.g., 1, 2, or 3 carbon-carbon triple bonds), and optionally one or more carbon-carbon double bonds (e.g., 1, 2, or 3 carbon-carbon double bonds). In some embodiments, C₂₋₄ alkynyl is particularly preferred. In certain embodiments, alkynyl does not contain any double bonds. The one or more carbon-carbon triple bonds can be internal (such as in 2-butynyl) or terminal (such as in 1-butynyl). Examples of the alkynyl groups include, without limitation, ethynyl (C₂), 1-propynyl (C₃), 2-propynyl (C₃), 1-butynyl (C₄), 2-butynyl (C₄), pentynyl (C₅), 3-methylbut-1-ynyl (C₅), hexynyl (C₆), and the like. “Cycloalkyl” refers to a radical of a non-aromatic cyclic hydrocarbon group having from 3-12, or 3-7 ring carbon atoms and zero heteroatoms. In some embodiments, C₃₋₆ cycloalkyl is especially preferred, and C₅₋₆ cycloalkyl is more preferred. Cycloalkyl also includes ring systems wherein the cycloalkyl ring, as defined above, is fused with one or more aryl or heteroaryl groups wherein the point of attachment is on the cycloalkyl ring, and in such instances, the number of carbons continue to designate the number of carbons in the cycloalkyl ring system. Exemplary cycloalkyl groups include, but is not limited to, cyclopropyl (C₃), cyclopropenyl (C₃), cyclobutyl (C₄), cyclobutenyl (C₄), cyclopentyl (C₅), cyclopentenyl (C₅), cyclohexyl (C₆), cyclohexenyl (C₆), cyclohexadienyl (C₆), cycloheptyl (C₇), cycloheptenyl (C₇), cycloheptadienyl (C₇), cycloheptatrienyl (C₇), and the like.

“Cycloalkylene” refers to the above mentioned cycloalkyl groups, having a pair of bonds bonding the cycloalkyl group between two other entities in the complex.

“Alkylamino” means a radical —NHR or —NR₂ where each R is independently an alkyl group. Representative examples of alkylamino groups include, but are not limited to, methylamino, methylamino, dimethylamino, (1-methylethyl)amino or i-propylamino, and di(1-methyethyl)amino or di(i-propyl)amino.

The term “hydroxyalkyl” means an alkyl radical as defined herein, substituted with one or more, preferably one, two or three hydroxy groups. Representative examples of hydroxyalkyl include, but are not limited to, hydroxymethyl, 2-hydroxyethyl, 2-hydroxypropyl, 3-hydroxypropyl, 1-(hydroxymethyl)-2-methylpropyl, 2-hydroxybutyl, 3-hydroxybutyl, 4-hydroxybutyl, 2,3-dihydroxypropyl, 2-hydroxy-1-hydroxymethylethyl, 2,3-dihydroxybutyl, 3,4-dihydroxybutyl and 2-(hydroxymethyl)-3-hydroxy-propyl, 2,3-dihydroxypropyl, and 1-(hydroxymethyl)2-hydroxyethyl.

The term “alkoxy,” as used herein, refers the radical —OR, where R is alkyl. Exemplary alkoxy groups include, but are not limited to, methoxy, ethoxy, and propoxy.

“Aromatic” or “aromatic group” refers to aryl, heteroaryl, arylene, or heteroarylene.

“Aryl” refers to optionally substituted carbocyclic aromatic groups (e.g., having 6-20, 6-14, or 6-10 carbon atoms). The aryl group includes phenyl, biphenyl, naphthyl, substituted phenyl, substituted biphenyl or substituted naphthyl.

“Arylene” refers to optionally substituted carbocyclic aromatic groups (e.g., having 6-20, 6-14, or 6-10 carbon atoms) having a pair of bonds bonding the aromatic group between two other entities in the complex. In some embodiments, the aryl group includes phenylene, biphenylene, naphthylene, substituted phenylene, substituted biphenylene or substituted naphthylene.

“Heteroaryl” refers to a radical of a 5-10 membered monocyclic or bicyclic 4n+2 aromatic ring system (e.g., having 6 or 10 π electrons shared in a cyclic array) having ring carbon atoms and 1-4 ring heteroatoms, wherein each heteroatom is independently selected from nitrogen, oxygen and sulfur. In heteroaryl groups that contain one or more nitrogen atoms, the point of attachment can be a carbon or nitrogen atom, as valency permits. Heteroaryl bicyclic ring systems can include one or more heteroatoms in one or both rings. Heteroaryl further includes ring systems wherein the heteroaryl ring, as defined above, is fused with one or more cycloalkyl, or heterocyclyl groups wherein the point of attachment is on the heteroaryl ring, and in such instances, the number of ring members continue to designate the number of ring members in the heteroaryl ring system. In some embodiments, C₅₋₆ heteroaryl is especially preferred, which is a radical of a 5-6 membered monocyclic or bicyclic 4n+2 aromatic ring system having ring carbon atoms and 1-4 ring heteroatoms. Unless otherwise specified, each instance of a heteroaryl group is independently optionally substituted, i.e., unsubstituted (an “unsubstituted heteroaryl”) or substituted (a “substituted heteroaryl”) with one or more substituents. In certain embodiments, the heteroaryl group is unsubstituted 5- to 10-membered heteroaryl. In certain embodiments, the heteroaryl group is substituted 5- to 10-membered heteroaryl. Exemplary 5-membered heteroaryl groups containing one heteroatom include, without limitation, pyrrolyl, furanyl and thiophenyl. Exemplary 5-membered heteroaryl groups containing two heteroatoms include, without limitation, imidazolyl, pyrazolyl, oxazolyl, isoxazolyl, thiazolyl, and isothiazolyl. Exemplary 5-membered heteroaryl groups containing three heteroatoms include, without limitation, triazolyl, oxadiazolyl, and thiadiazolyl. Exemplary 5-membered heteroaryl groups containing four heteroatoms include, without limitation, tetrazolyl. Exemplary 6-membered heteroaryl groups containing one heteroatom include, without limitation, pyridinyl. Exemplary 6-membered heteroaryl groups containing two heteroatoms include, without limitation, pyridazinyl, pyrimidinyl, and pyrazinyl. Exemplary 6-membered heteroaryl groups containing three or four heteroatoms include, without limitation, triazinyl and tetrazinyl, respectively. Exemplary 7-membered heteroaryl groups containing one heteroatom include, without limitation, azepinyl, oxepinyl, and thiepinyl. Exemplary 5,6-bicyclic heteroaryl groups include, without limitation, indolyl, isoindolyl, indazolyl, benzotriazolyl, benzothiophenyl, isobenzothiophenyl, benzofuranyl, benzoisofuranyl, benzimidazolyl, benzoxazolyl, benzisoxazolyl, benzoxadiazolyl, benzthiazolyl, benzisothiazolyl, benzthiadiazolyl, indolizinyl, and purinyl. Exemplary 6,6-bicyclic heteroaryl groups include, without limitation, naphthyridinyl, pteridinyl, quinolinyl, isoquinolinyl, cinnolinyl, quinoxalinyl, phthalazinyl, and quinazolinyl.

“Heteroarylene” refers to optionally substituted heteroaryl groups, having a pair of bonds bonding the heteroaryl group between two other entities in the complex.

“Heterocyclyl” refers to a radical of a 3- to 8-membered non-aromatic ring system having ring carbon atoms and 1 to 3 ring heteroatoms, wherein each heteroatom is independently selected from nitrogen, oxygen, sulfur, boron, phosphorus, and silicon, wherein the carbon, nitrogen, sulfur and phosphorus atoms may be present in the oxidation state, such as C(O), S(O), S(O)₂, P(O), and the like. In heterocyclyl groups that contain one or more nitrogen atoms, the point of attachment can be a carbon or nitrogen atom, as valency permits. In some embodiments, 4- to 7-membered heterocyclyl is preferred, which is a radical of a 4- to 7-membered non-aromatic ring system having ring carbon atoms and 1 to 3 ring heteroatoms. In some embodiments, 5- to 8-membered heterocyclyl is preferred, which is a radical of a 5- to 8-membered non-aromatic ring system having ring carbon atoms and 1 to 3 ring heteroatoms. In some embodiments, 4- to 6-membered heterocyclyl is preferred, which is a radical of a 4- to 6-membered non-aromatic ring system having ring carbon atoms and 1 to 3 ring heteroatoms. In some embodiments, 5- to 6-membered heterocyclyl is preferred, which is a radical of a 5- to 6-membered non-aromatic ring system having ring carbon atoms and 1 to 3 ring heteroatoms. In some embodiments, 5-membered heterocyclyl is more preferred, which is a radical of a 5-membered non-aromatic ring system having ring carbon atoms and 1 to 3 ring heteroatoms. In some embodiments, the 3- to 8-membered heterocyclyl, 4- to 7-membered heterocyclyl, 5- to 8-membered heterocyclyl, 4- to 6-membered heterocyclyl, 5- to 6-membered heterocyclyl and 5-membered heterocyclyl contain 1 to 3 (more preferably 1 or 2) ring heteroatoms selected from nitrogen, oxygen and sulfur (preferably nitrogen and oxygen). Unless otherwise specified, each instance of heterocyclyl is independently optionally substituted, i.e., unsubstituted (an “unsubstituted heterocyclyl”) or substituted (a “substituted heterocyclyl”) with one or more substituents. In certain embodiments, the heterocyclyl group is unsubstituted 3-8 membered heterocyclyl. In certain embodiments, the heterocyclyl group is substituted 3-8 membered heterocyclyl. Heterocyclyl also includes ring systems wherein the heterocyclyl ring, as defined above, is fused with one or more carbocyclyl groups wherein the point of attachment is on the carbocyclyl ring, or ring systems wherein the heterocyclyl ring, as defined above, is fused with one or more aryl or heteroaryl groups, wherein the point of attachment is on the heterocyclyl ring; and in such instances, the number of ring members continue to designate the number of ring members in the heterocyclyl ring system. Exemplary 3-membered heterocyclyl groups containing one heteroatom include, without limitation, azirdinyl, oxiranyl, thiorenyl. Exemplary 4-membered heterocyclyl groups containing one heteroatom include, without limitation, azetidinyl, oxetanyl and thietanyl. Exemplary 5-membered heterocyclyl groups containing one heteroatom include, without limitation, tetrahydrofuranyl, dihydrofuranyl, tetrahydrothiophenyl, dihydrothiophenyl, pyrrolidinyl, dihydropyrrolyl and pyrrolyl-2,5-dione. Exemplary 5-membered heterocyclyl groups containing two heteroatoms include, without limitation, dioxolanyl, oxathiolanyl, oxathiolyl (1,2-oxathiolyl, 1,3-oxathiolyl), dithiolanyl, dihydropyrazolyl, dihydroimidazolyl, dihydrothiazolyl, dihydroisothiazolyl, dihydrooxazolyl, dihydroisoxazolyl, dihydrooxadiazolyl and oxazolidin-2-one. Exemplary 5-membered heterocyclyl groups containing three heteroatoms include, without limitation, triazolinyl, oxadiazolinyl, and thiadiazolinyl. Exemplary 6-membered heterocyclyl groups containing one heteroatom include, without limitation, piperidinyl, tetrahydropyranyl, dihydropyridinyl, tetrahydropyridinyl, and thianyl. Exemplary 6-membered heterocyclyl groups containing two heteroatoms include, without limitation, dihydropyrazinyl, piperazinyl, morpholinyl, dithianyl, dioxanyl. Exemplary 6-membered heterocyclyl groups containing two heteroatoms include, without limitation, triazinanyl. Exemplary 7-membered heterocyclyl groups containing one or two heteroatoms include, without limitation, azepanyl, diazepanyl, oxepanyl and thiepanyl. Exemplary 8-membered heterocyclyl groups containing one or two heteroatoms include, without limitation, azocanyl, oxecanyl, thiocanyl, octahydrocyclopenta[c]pyrrolyl and octahydropyrrolo[3,4-c]pyrrolyl. Exemplary 5-membered heterocyclyl groups fused to a C₆ aryl ring (also referred to herein as a 5,6-bicyclic heterocyclic ring) include, without limitation, indolinyl, isoindolinyl, dihydrobenzofuranyl, dihydrobenzothienyl, benzoxazolinonyl, and the like. Exemplary 6-membered heterocyclyl groups fused to an C₆ aryl ring (also referred to herein as a 6,6-bicyclic heterocyclic ring) include, without limitation, tetrahydroquinolinyl, tetrahydroisoquinolinyl, and the like.

“Heterocyclene” refers to optionally substituted heterocyclyl groups, having a pair of bonds bonding the heterocyclyl group between two other entities in the complex.

“Aralkyl” refers to an alkyl group which is substituted with an aryl group. Some non-limiting examples of aralkyl include benzyl and phenethyl.

“Acyl” refers to a monovalent group of the formula —C(═O)H, —C(═O)-alkyl, —C(═O)-aryl, —C(═O)-aralkyl, or —C(═O)-alkaryl.

“Halogen” refers to fluorine, chlorine, bromine and iodine.

“Styryl” refers to a univalent radical C₆H₅—CH═CH— derived from styrene.

“Substituted” as used herein to describe a compound or chemical moiety refers to that at least one hydrogen atom of that compound or chemical moiety is replaced with a non-hydrogen chemical moiety. Non-limiting examples of substituents are those found in the exemplary compounds and embodiments disclosed herein, as well as halogen; alkyl; heteroalkyl; alkenyl; alkynyl; aryl; heteroaryl; hydroxy; alkoxyl; amino; nitro; thiol; thioether; imine; cyano; amido; phosphonato; phosphine; carboxyl; thiocarbonyl; sulfonyl; sulfonamide; ketone; aldehyde; ester; oxo; haloalkyl (e.g., trifluoromethyl); carbocyclic cycloalkyl, which can be monocyclic or fused or non-fused polycyclic (e.g., cyclopropyl, cyclobutyl, cyclopentyl or cyclohexyl) or a heterocycloalkyl, which can be monocyclic or fused or non-fused polycyclic (e.g., pyrrolidinyl, piperidinyl, piperazinyl, morpholinyl or thiazinyl); carbocyclic or heterocyclic, monocyclic or fused or non-fused polycyclic aryl (e.g., phenyl, naphthyl, pyrrolyl, indolyl, furanyl, thiophenyl, imidazolyl, oxazolyl, isoxazolyl, thiazolyl, triazolyl, tetrazolyl, pyrazolyl, pyridinyl, quinolinyl, isoquinolinyl, acridinyl, pyrazinyl, pyridazinyl, pyrimidinyl, benzimidazolyl, benzothiophenyl or benzofuranyl); amino (primary, secondary or tertiary); O-lower alkyl; O-aryl, aryl; aryl-lower alkyl; —CO₂CH₃; —CONH₂; —OCH₂CONH₂; NH₂; —SO₂NH₂; —OCHF₂; —CF₃; —OCF₃; —NH(alkyl); —N(alkyl)₂; —NH(aryl); —N(alkyl)(aryl); —N(aryl)₂; —CHO; —CO(alkyl); —CO(aryl); —CO₂(alkyl); and —CO₂(aryl); and such moieties can also be optionally substituted by a fused-ring structure or bridge, for example —OCH₂O—. These substituents can optionally be further substituted with a substituent selected from such groups. All chemical groups disclosed herein can be substituted, unless it is specified otherwise. For example, “substituted” alkyl, alkenyl, alkynyl, aryl, hydrocarbyl or heterocyclo moieties described herein are moieties which are substituted with a hydrocarbyl moiety, a substituted hydrocarbyl moiety, a heteroatom, or a heterocyclo. Further, substituents may include moieties in which a carbon atom is substituted with a heteroatom such as nitrogen, oxygen, silicon, phosphorus, boron, sulfur, or a halogen atom. These substituents may include halogen, heterocyclo, alkoxy, alkenoxy, alkynoxy, aryloxy, hydroxy, protected hydroxy, keto, acyl, acyloxy, nitro, amino, amido, cyano, thiol, ketals, acetals, esters and ethers.

In an embodiment of the invention an OLED emitter is a tungsten(VI) emitter of the structure:

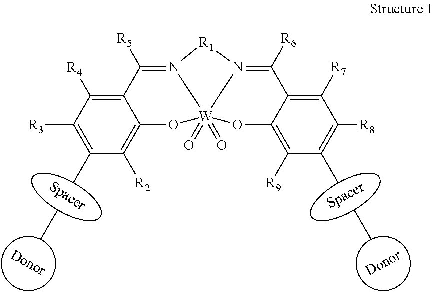

where: W is tungsten in an oxidation state of VI; R₁ is a connector between imine (C═N) units selected from a single bond or a bridge comprising a plurality of atoms and bonds, including, but not limited to, —O—, —S—, substituted or unsubstituted C₁-C₆ alkylene, substituted or unsubstituted C₃-C₁₂ cycloalkylene, C₂-C₈ alkenylene, substituted or unsubstituted C₆-C₁₀ arylene, sulfonyl, carbonyl, —CH(OH)—, 5-8 member heterocyclene group, any combination thereof, or any combination thereof with —C(═O)O—, —O—C(═O)—; optionally, spacers, each of which connecting a donor with the W(VI) cis-dioxo Schiff base core, independently being a single bond, an unsubstituted or substituted arylene or heteroarylene; donors that are electron rich unsubstituted or substituted diaryl amine or an unsubstituted or substituted nitrogen heterocyclic aromatic of the structure:

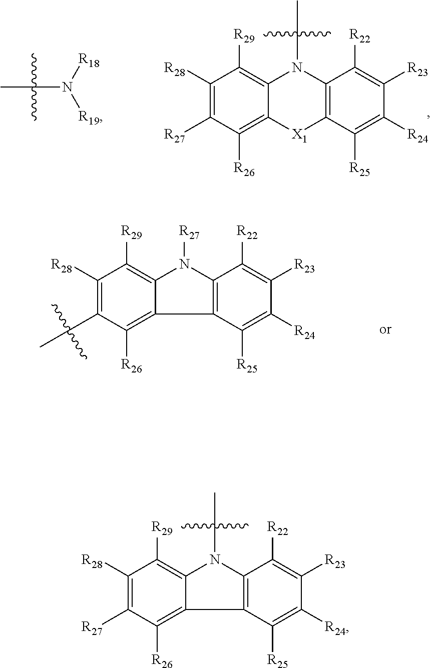

where: R₁₈-R₁₉ are independently hydrogen, unsubstituted alkyl, substituted alkyl, unsubstituted cycloalkyl, substituted cycloalkyl, unsubstituted aryl, substituted aryl, acyl, unsubstituted aralkyl, unsubstituted aralkyl, styryl, aryloxycarbonyl, phenoxycarbonyl, or an alkoxycarbonyl group, where a pair of adjacent R groups of R₁₈-R₁₉ can independently form a 5-8 member heterocyclic ring; and R₂₂-R₂₉ are independently hydrogen, halogen, hydroxyl, an unsubstituted alkyl, a substituted alkyl, cycloalkyl, unsubstituted aryl, substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, or alkoxycarbonyl and X₁ is selected from CH₂, CHR, CR₂, O, S, NH, NR, PR, or SiR₂ where R is independently hydrogen, unsubstituted alkyl, a substituted alkyl, cycloalkyl, unsubstituted aryl, substituted aryl, acyl, unsubstituted aralkyl, substituted aralkyl, or styryl; and a W(VI) cis-dioxo Schiff base core where R₂-R₉ are independently hydrogen, halogen, hydroxyl, unsubstituted alkyl, substituted alkyl, cycloalkyl, unsubstituted aryl, substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, an alkoxycarbonyl group or where any pair of adjacent R groups and substituents on a spacer that is separated by three or four bonds can form a substituted or unsubstituted 5-8 member cycloalkyl, aryl, heterocycle, or heteroaryl ring. The spacer can be absent with the donor bonded directly to the W(VI) cis-dioxo Schiff base core by a single bond. The cis-dioxo Schiff base core is formed by the complexation of W(VI) with the intermediate ligand where the di-phenol is deprotonated upon forming the complex. The tungsten is in +6 oxidation state and has an octahedral geometry. The coordination sites of the tungsten center are occupied by the cis-dioxo Schiff base tetradentate ligand.

In an embodiment of the invention the spacer is a phenylene unit and the tungsten(VI) emitter of structure I is:

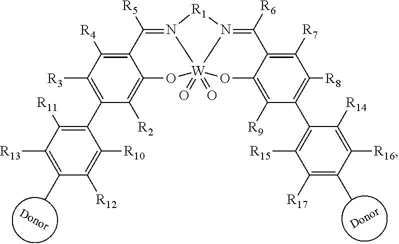

where R₁₁-R₁₇ are independently selected from hydrogen, halogen, hydroxyl, unsubstituted alkyl, substituted alkyl, cycloalkyl, unsubstituted aryl, substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, alkoxycarbonyl group, and where one or more of R₁₁ and R₁₃, R₁₀ and R₁₂, R₁₄ and R₁₆, R₁₅ and R₁₇, and when donors are

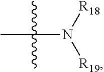

R₁₃ and R₁₈, R₁₂ and R₁₈, R₁₆ and R₁₈, R₁₇ and R₁₈ in combination can be a portion of a 5-8 member ring.

The a tungsten(VI) emitter display a donor, which can be connected by a spacer, that is meta to the oxygen site of the tetradentate ligand of the complex and para to an imine site of the tetradentate ligand cis-dioxo Schiff base tetradentate ligand. The spacer group can vary and be substituted to control the dihedral angle between the tetradentate ligand core, the spacer and the donor portions to define the singlet-triplet energy gap to affect the intersystem crossing of the system that defines the fluorescence and phosphorescence of the emitter. This relationship between the donor and oxygen site of ligation favorably enhances the luminescence of the complex.

Non-limiting examples for the tungsten(VI) emitters of Structure I are shown in Table 1, below.

TABLE 1

| | |
|---|---|
| 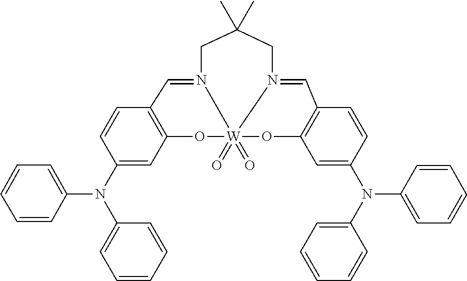 | Emitter 101 |
| 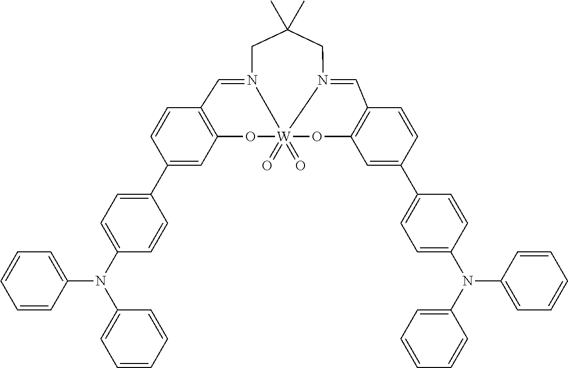 | Emitter 102 |
| 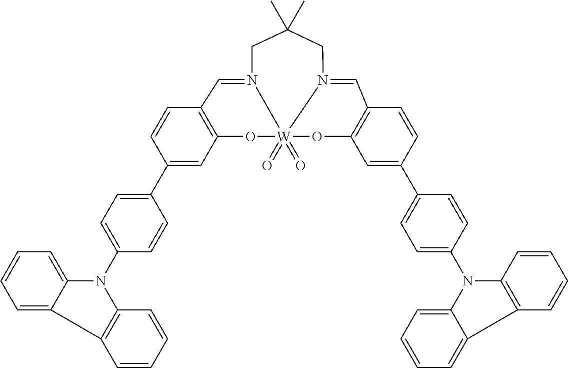 | Emitter 103 |
| 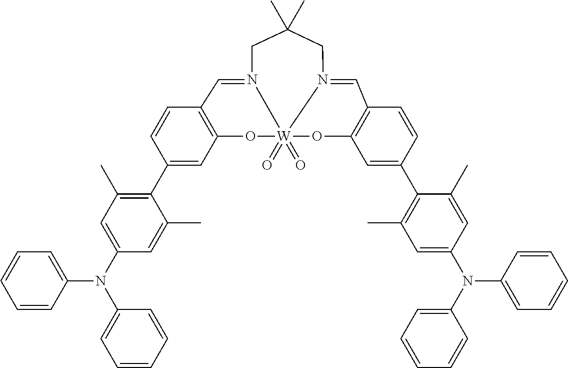 | Emitter 104 |
| 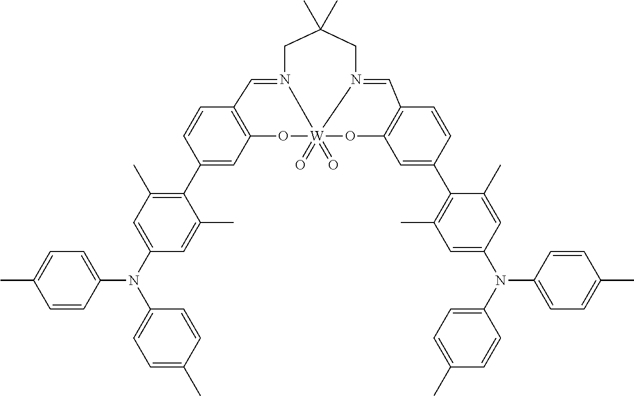 | Emitter 105 |
| 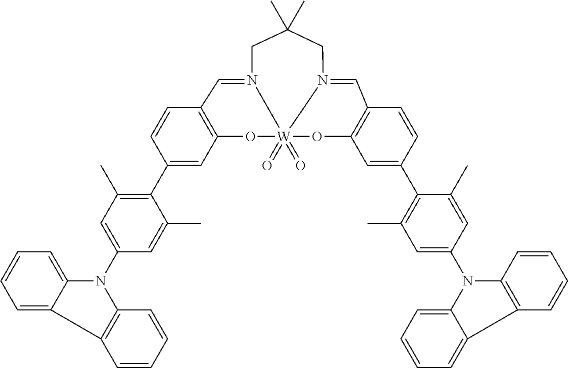 | Emitter 106 |
| 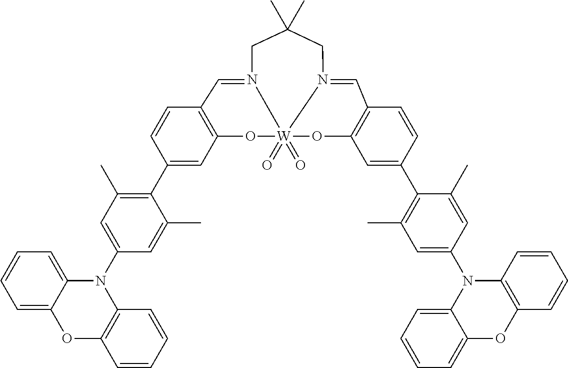 | Emitter 107 |
| 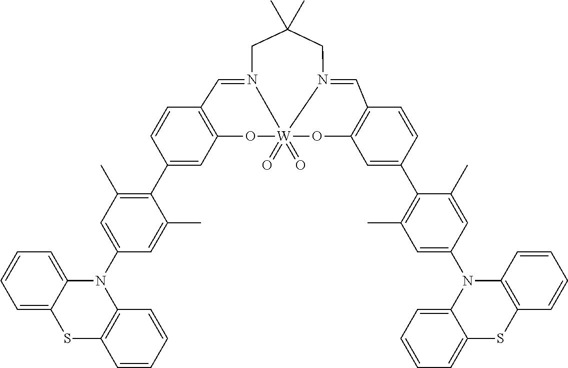 | Emitter 108 |
| 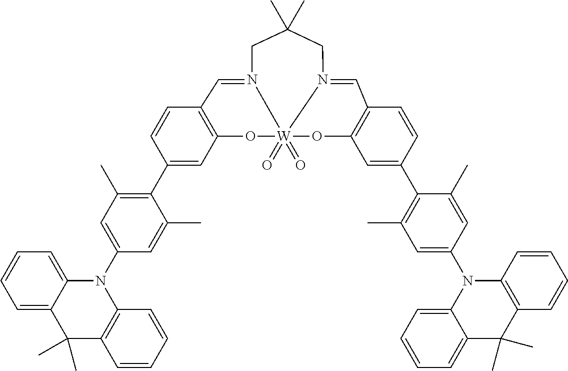 | Emitter 109 |
| 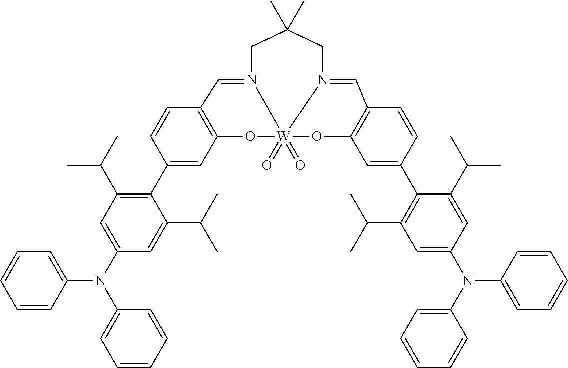 | Emitter 110 |
| 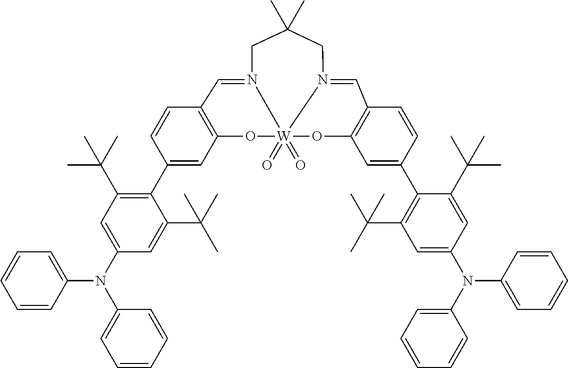 | Emitter 111 |
| 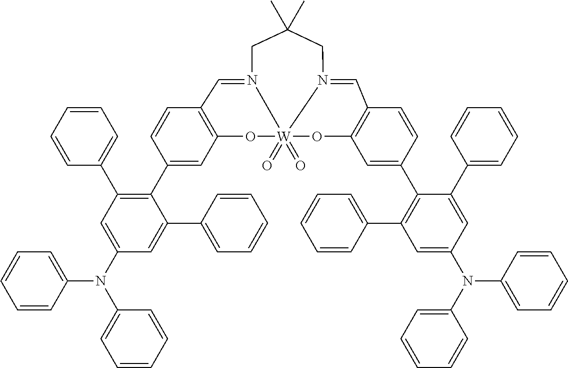 | Emitter 112 |
| 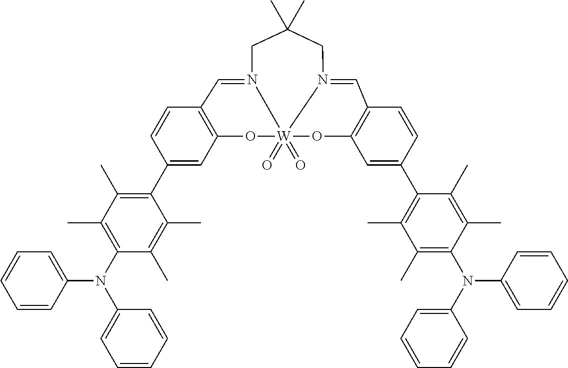 | Emitter 113 |
| 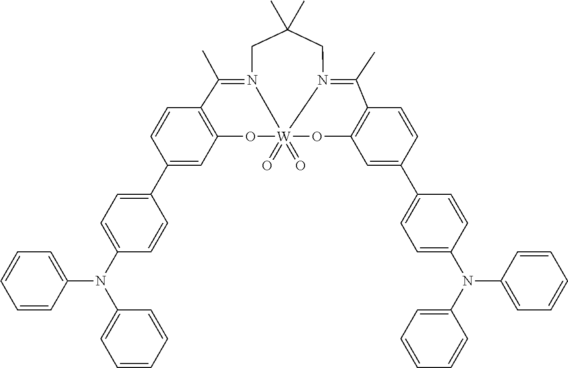 | Emitter 114 |
| 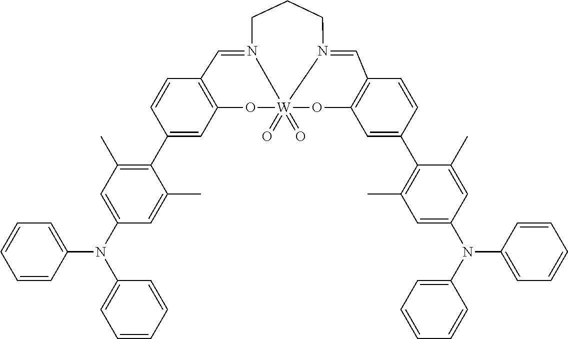 | Emitter 115 |
| 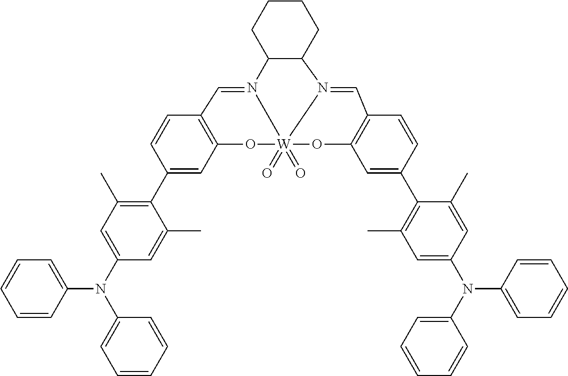 | Emitter 116 |
| 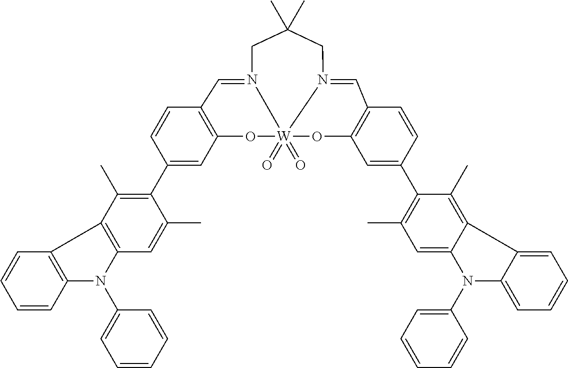 | Emitter 117 |
| 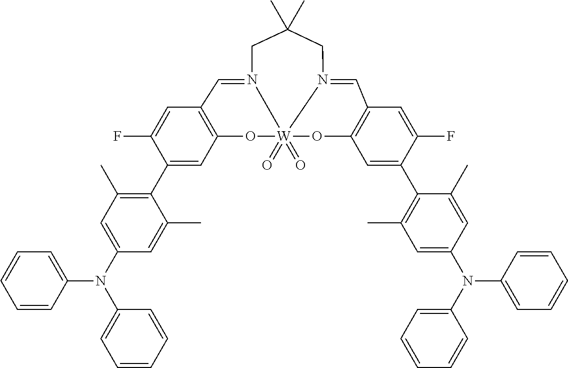 | Emitter 118 |
| 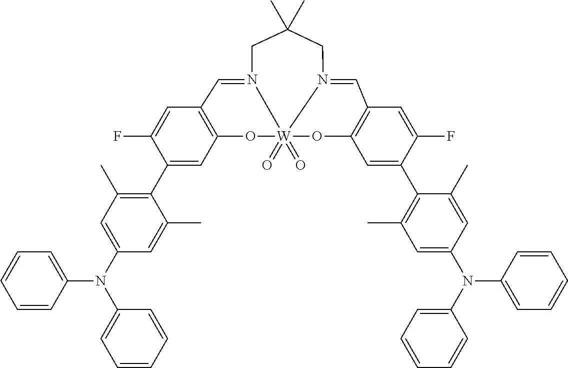 | Emitter 119 |
| 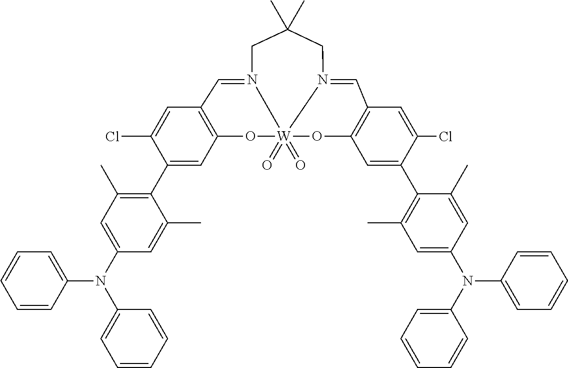 | Emitter 120 |
| 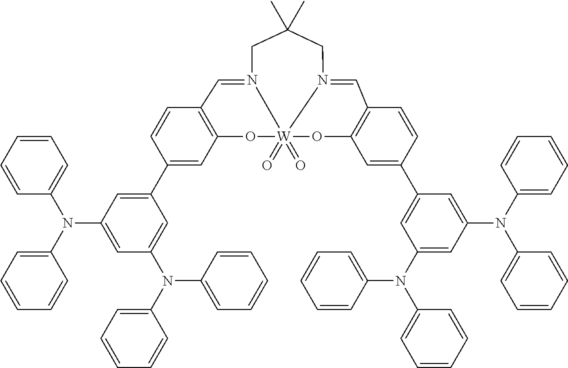 | Emitter 121 |
| 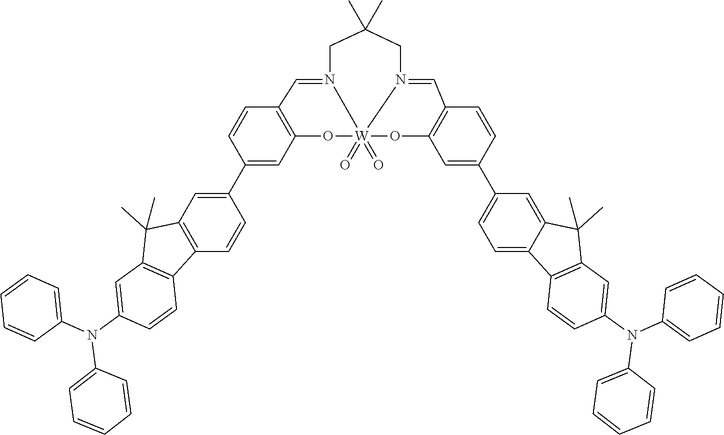 | Emitter 122 |

Another embodiment of the invention is directed to a di-donor comprising di-hydroxy Schiff base tetradentate ligand of the structure:

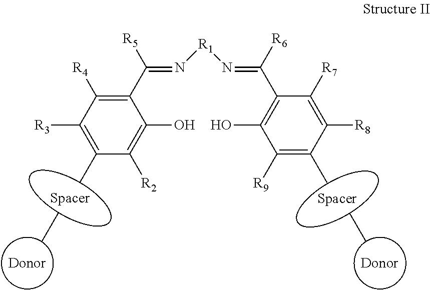

where R₁-R₉ the spacers, and the donors are as defined above for the tungsten(VI) emitter of Structure I, above. Structure II are prepared as substituted salicylaldehyde Schiff base adducts of the same or different substituted salicylaldehydes and a symmetric or assymetric diamine. The di-donor comprising di hydroxy Schiff base tetradentate ligand can be a single compound, or it may be a statistical combination of three or more ligands from a plurality of substituted salicylaldehydes and\or a plurality of diamines. In this manner, a combination of emitters with different wavelengths of emissions can be formed in a single synthesis upon complexation of the ligand mixture with a tungsten (VI) salt.

In an embodiment of the invention the shift base tetradentate ligand of Structure II is:

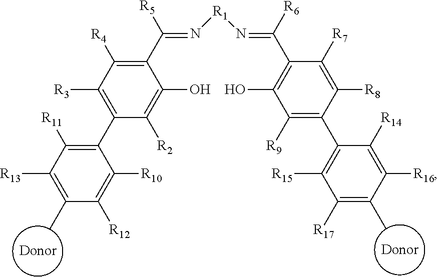

where R₁₁-R₁₇ are independently selected from hydrogen, halogen, hydroxyl, unsubstituted alkyl, substituted alkyl, cycloalkyl, unsubstituted aryl, substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, alkoxycarbonyl group, and where one or more of R₁₁ and R₁₃, R₁₀ and R₁₂, R₁₄ and R₁₆, R₁₅ and R₁₇, and when donors are

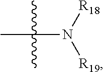

R₁₃ and R₁₈, R₁₂ and R₁₈, R₁₆ and R₁₈, R₁₇ and R₁₈ in combination can be a portion of a 5-8 member ring.

Non-limiting examples for the di-hydroxy Schiff base tetradentate ligand of Structure II are shown in Table 2, below.

TABLE 2

| | |
|---|---|
| 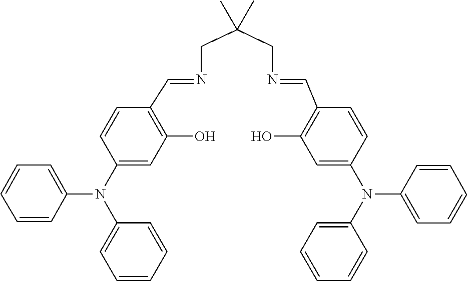 [SMILES: CC(C)(C/N=C/c1ccc(N(c2ccccc2)c2ccccc2)cc1O)C/N=C/c1ccc(N(c2ccccc2)c2ccccc2)cc1O] | Ligand 601 |
| 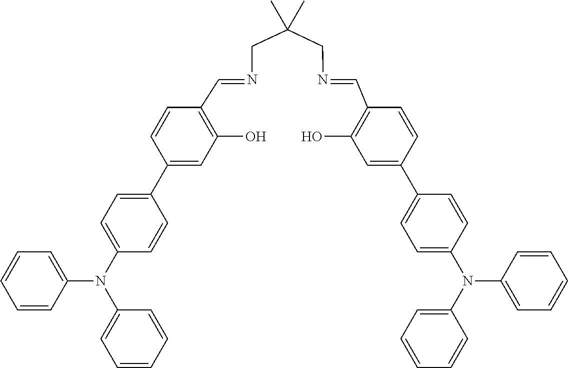 [SMILES: CC(C)(C/N=C/c1ccc(-c2ccc(N(c3ccccc3)c3ccccc3)cc2)cc1O)C/N=C/c1ccc(-c2ccc(N(c3ccccc3)c3ccccc3)cc2)cc1O] | Ligand 602 |
| 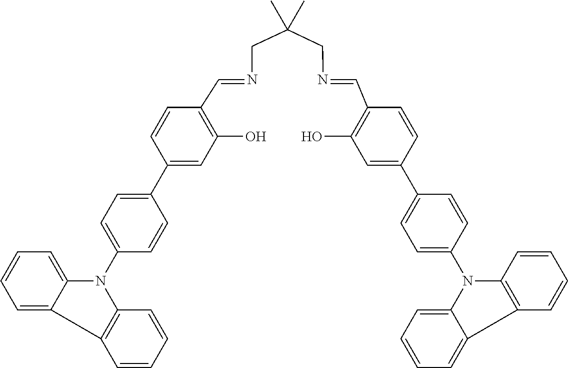 [SMILES: CC(C)(C/N=C/c1ccc(-c2ccc(-n3c4ccccc4c4ccccc43)cc2)cc1O)C/N=C/c1ccc(-c2ccc(-n3c4ccccc4c4ccccc43)cc2)cc1O] | Ligand 603 |
| 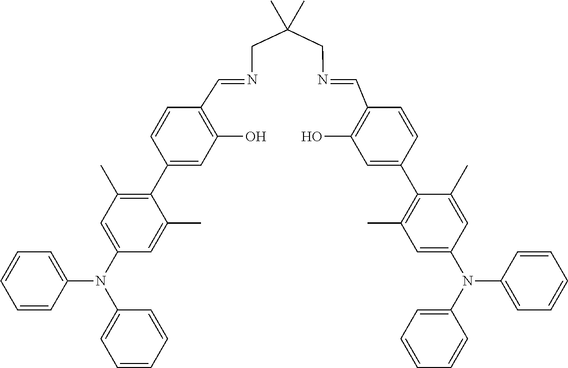 [SMILES: Cc1cc(N(c2ccccc2)c2ccccc2)cc(C)c1-c1ccc(/C=N/CC(C)(C)C/N=C/c2ccc(-c3c(C)cc(N(c4ccccc4)c4ccccc4)cc3C)cc2O)c(O)c1] | Ligand 604 |
| 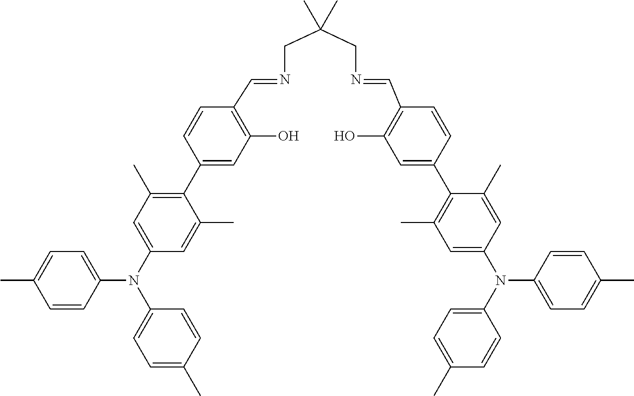 | Ligand 605 |
| 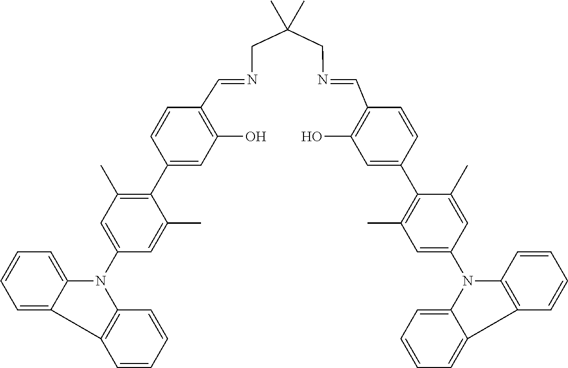 [SMILES: Cc1cc(-n2c3ccccc3c3ccccc32)cc(C)c1-c1ccc(/C=N/CC(C)(C)C/N=C/c2ccc(-c3c(C)cc(-n4c5ccccc5c5ccccc54)cc3C)cc2O)c(O)c1] | Ligand 606 |
| 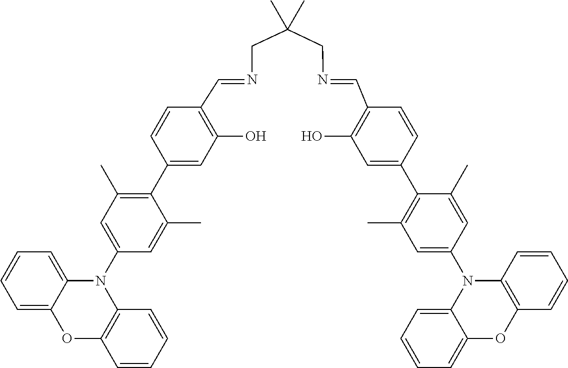 [SMILES: Cc1cc(N2c3ccccc3Oc3ccccc32)cc(C)c1-c1ccc(/C=N/CC(C)(C)C/N=C/c2ccc(-c3c(C)cc(N4c5ccccc5Oc5ccccc54)cc3C)cc2O)c(O)c1] | Ligand 607 |
| 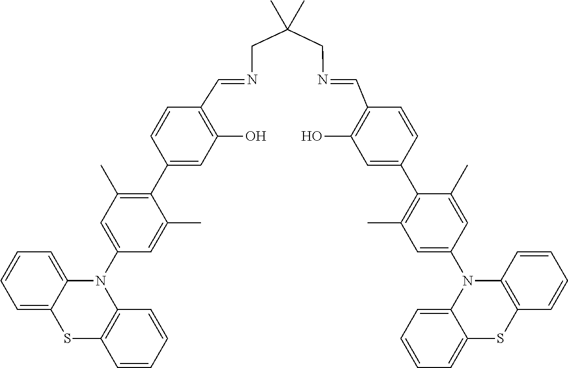 [SMILES: Cc1cc(N2c3ccccc3Sc3ccccc32)cc(C)c1-c1ccc(/C=N/CC(C)(C)C/N=C/c2ccc(-c3c(C)cc(N4c5ccccc5Sc5ccccc54)cc3C)cc2O)c(O)c1] | Ligand 608 |
| 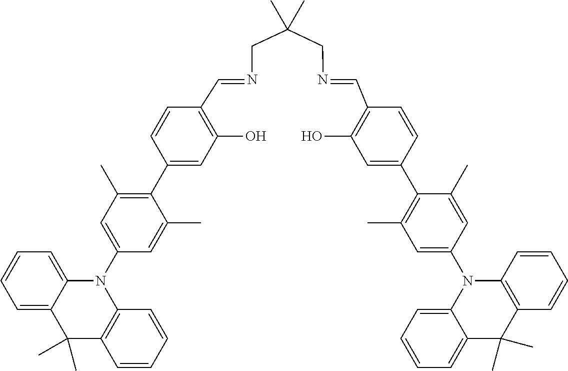 [SMILES: Cc1cc(N2c3ccccc3C(C)(C)c3ccccc32)cc(C)c1-c1ccc(/C=N/CC(C)(C)C/N=C/c2ccc(-c3c(C)cc(N4c5ccccc5C(C)(C)c5ccccc54)cc3C)cc2O)c(O)c1] | Ligand 609 |
| 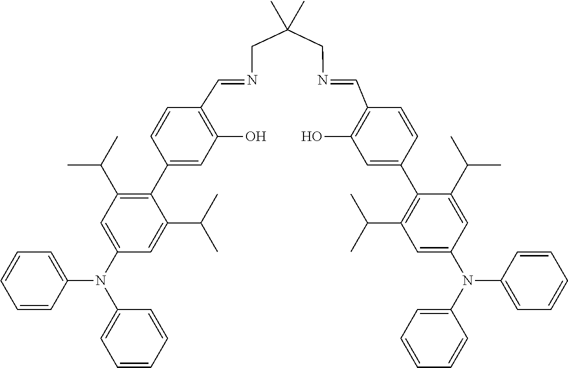 [SMILES: CC(C)c1cc(N(c2ccccc2)c2ccccc2)cc(C(C)C)c1-c1ccc(/C=N/CC(C)(C)C/N=C/c2ccc(-c3c(C(C)C)cc(N(c4ccccc4)c4ccccc4)cc3C(C)C)cc2O)c(O)c1] | Ligand 610 |
| 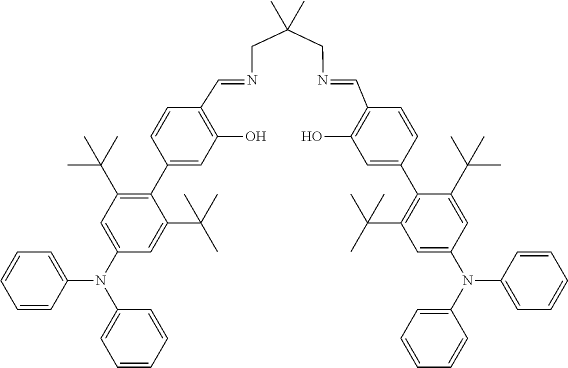 [SMILES: CC(C)(C/N=C/c1ccc(-c2c(C(C)(C)C)cc(N(c3ccccc3)c3ccccc3)cc2C(C)(C)C)cc1O)C/N=C/c1ccc(-c2c(C(C)(C)C)cc(N(c3ccccc3)c3ccccc3)cc2C(C)(C)C)cc1O] | Ligand 611 |
| 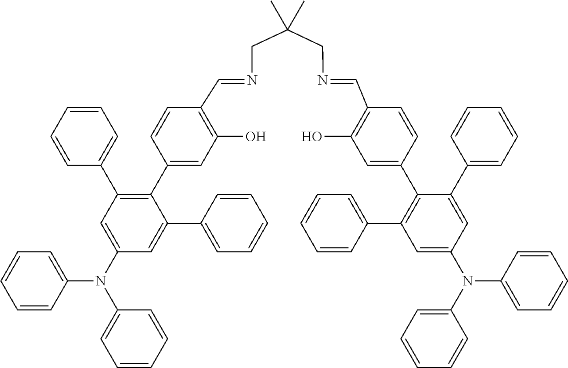 [SMILES: CC(C)(C/N=C/c1ccc(-c2c(-c3ccccc3)cc(N(c3ccccc3)c3ccccc3)cc2-c2ccccc2)cc1O)C/N=C/c1ccc(-c2c(-c3ccccc3)cc(N(c3ccccc3)c3ccccc3)cc2-c2ccccc2)cc1O] | Ligand 612 |
| 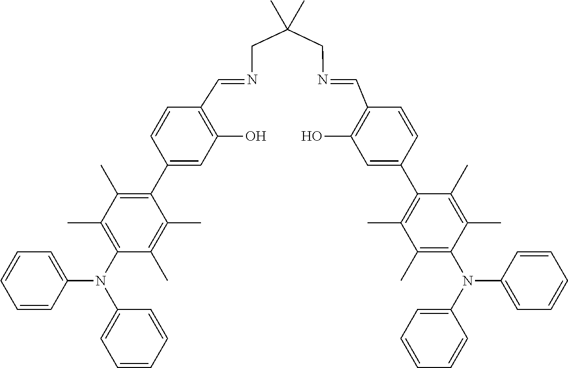 [SMILES: Cc1c(C)c(N(c2ccccc2)c2ccccc2)c(C)c(C)c1-c1ccc(/C=N/CC(C)(C)C/N=C/c2ccc(-c3c(C)c(C)c(N(c4ccccc4)c4ccccc4)c(C)c3C)cc2O)c(O)c1] | Ligand 613 |
| 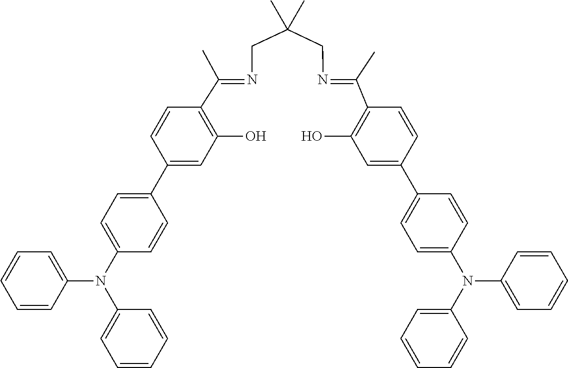 [SMILES: C/C(=N\CC(C)(C)C/N=C(\C)c1ccc(-c2ccc(N(c3ccccc3)c3ccccc3)cc2)cc1O)c1ccc(-c2ccc(N(c3ccccc3)c3ccccc3)cc2)cc1O] | Ligand 614 |
| 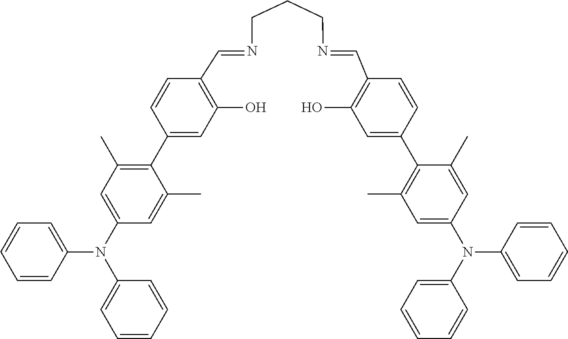 [SMILES: Cc1cc(N(c2ccccc2)c2ccccc2)cc(C)c1-c1ccc(/C=N/CCC/N=C/c2ccc(-c3c(C)cc(N(c4ccccc4)c4ccccc4)cc3C)cc2O)c(O)c1] | Ligand 615 |
| 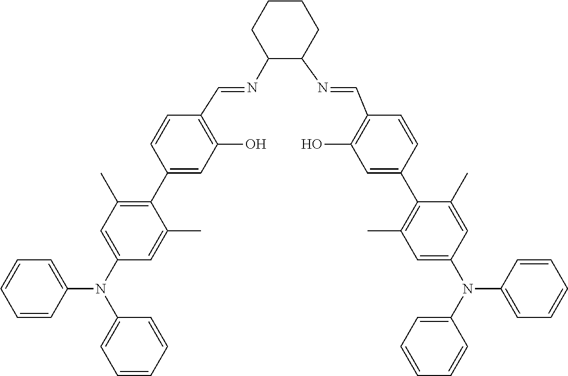 [SMILES: Cc1cc(N(c2ccccc2)c2ccccc2)cc(C)c1-c1ccc(/C=N/C2CCCCC2/N=C/c2ccc(-c3c(C)cc(N(c4ccccc4)c4ccccc4)cc3C)cc2O)c(O)c1] | Ligand 616 |
| 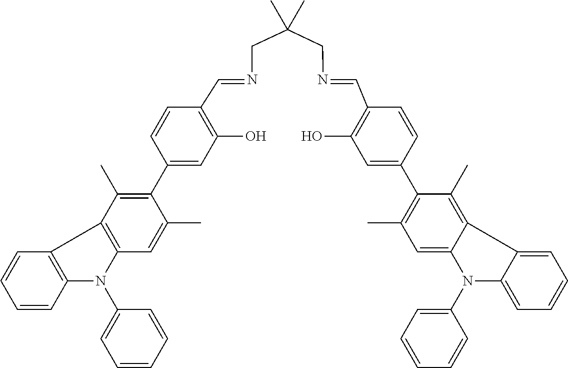 [SMILES: Cc1cc2c(c(C)c1-c1ccc(/C=N/CC(C)(C)C/N=C/c3ccc(-c4c(C)cc5c(c4C)c4ccccc4n5-c4ccccc4)cc3O)c(O)c1)c1ccccc1n2-c1ccccc1] | Ligand 617 |
| 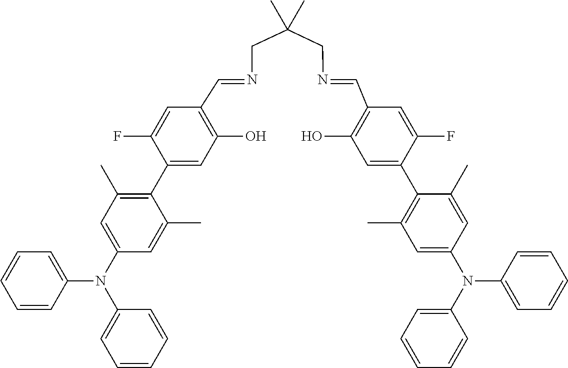 [SMILES: Cc1cc(N(c2ccccc2)c2ccccc2)cc(C)c1-c1cc(O)c(/C=N/CC(C)(C)C/N=C/c2cc(F)c(-c3c(C)cc(N(c4ccccc4)c4ccccc4)cc3C)cc2O)cc1F] | Ligand 618 |
| 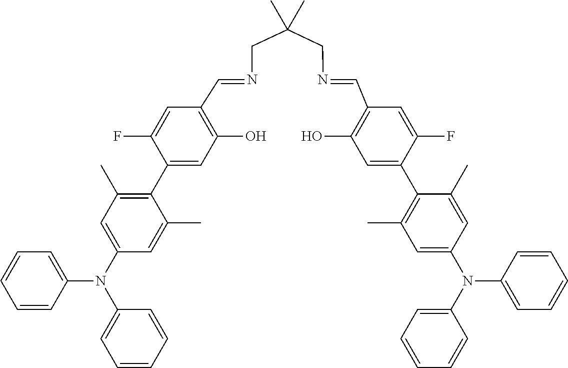 [SMILES: Cc1cc(N(c2ccccc2)c2ccccc2)cc(C)c1-c1cc(O)c(/C=N/CC(C)(C)C/N=C/c2cc(F)c(-c3c(C)cc(N(c4ccccc4)c4ccccc4)cc3C)cc2O)cc1F] | Ligand 619 |
| 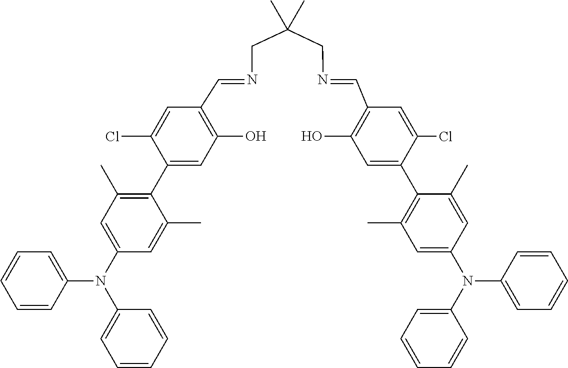 [SMILES: Cc1cc(N(c2ccccc2)c2ccccc2)cc(C)c1-c1cc(O)c(/C=N/CC(C)(C)C/N=C/c2cc(Cl)c(-c3c(C)cc(N(c4ccccc4)c4ccccc4)cc3C)cc2O)cc1Cl] | Ligand 620 |
| 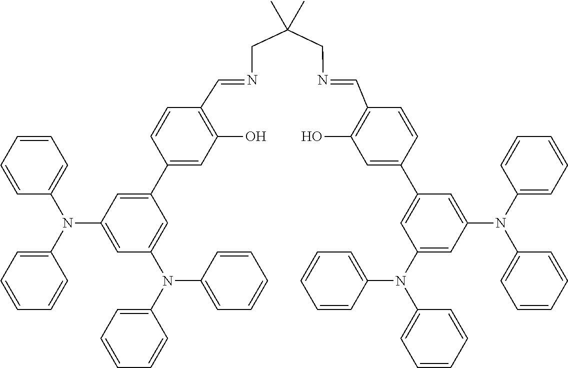 [SMILES: CC(C)(C/N=C/c1ccc(-c2cc(N(c3ccccc3)c3ccccc3)cc(N(c3ccccc3)c3ccccc3)c2)cc1O)C/N=C/c1ccc(-c2cc(N(c3ccccc3)c3ccccc3)cc(N(c3ccccc3)c3ccccc3)c2)cc1O] | Ligand 621 |
| 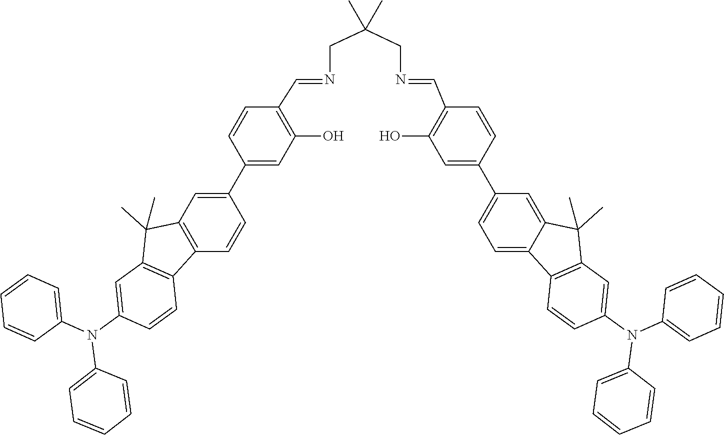 [SMILES: CC(C)(C/N=C/c1ccc(-c2ccc3c(c2)C(C)(C)c2cc(N(c4ccccc4)c4ccccc4)ccc2-3)cc1O)C/N=C/c1ccc(-c2ccc3c(c2)C(C)(C)c2cc(N(c4ccccc4)c4ccccc4)ccc2-3)cc1O] | Ligand 622 |

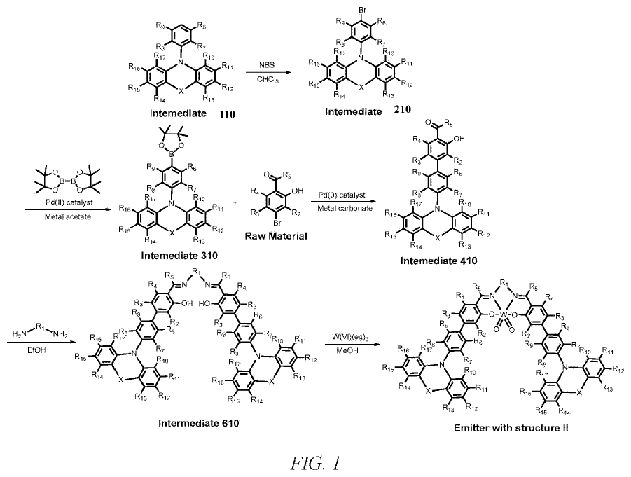

In an embodiment of the invention, the tungsten(VI) emitters with chemical structure of Structure I are prepared by reacting the corresponding ligands with a tungsten salt in the presence of a solvent or mixed solvent. An exemplary multistep synthesis for the preparation of intermediate ligand 610 and its conversion to Emitters by reaction with a tungsten(VI) salt is shown in FIG. 1.

In an embodiment of the invention, a light-emitting device comprises at least one OLED emitter of Structure I. The device can be a light-emitting diode (LED) and may be fabricated by vacuum deposition or by a solution process. The device can employ the tungsten(VI) emitters at a dopant concentration greater than 4 wt. %. The device can have one or more emissive layers comprising one or more OLED emitters in each layer.

The OLED emitter of Structure I, such as where the spacer is a phenylene unit, can be used in all apparatus in which electroluminescence is useful. Suitable devices are preferably selected from stationary and mobile visual display units and illumination units. Stationary visual display units are, for example, visual display units of computers, televisions, visual display units in printers, kitchen appliances and advertising panels, illuminations and information panels. Mobile visual display units are, for example, visual display units in cellphones, tablet PCs, laptops, digital cameras, MP3 players, vehicles and destination displays on buses and trains. Other devices in which the inventive OLED emitter of Structure I such as where the spacer is a phenylene unit, can be used include, but are not limited to, keyboards, items of clothing, furniture, and wallpaper. In addition, the present invention relates to a device selected from the group consisting of stationary visual display units such as visual display units of computers, televisions, visual display units in printers, kitchen appliances and advertising panels, illuminations, information panels, and mobile visual display units such as visual display units in cellphones, tablet PCs, laptops, digital cameras, MP3 players, vehicles and destination displays on buses and trains, illumination units, keyboards, items of clothing, furniture, and wallpaper, comprising at least one inventive organic light-emitting diode or at least one inventive light-emitting layer.

Methods and Materials

The following non-limiting examples illustrate the preparation the structure, and the properties that demonstrate the utility of the tungsten(VI) emitters, according to an embodiment of the invention. All percentages are by weight and all solvent mixture proportions are by volume unless otherwise noted.

Preparation of Intermediate 205

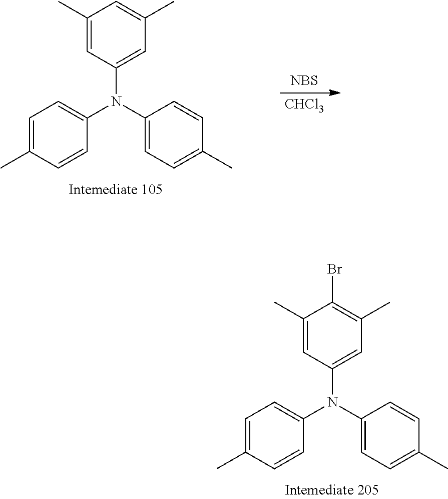

To a solution of 3,5-dimethyl-N,N-di-p-tolylaniline (Intermediate 105) (4.12 g, 13.7 mmol) in 50 mL CHCl₃, N-bromosuccinimide (2.43 g, 13.7 mmol) was added in portions. The mixture was stirred at room temperature for 2 hours. The crude product was extracted with CHCl₃/H₂O. Solvent was removed under reduced pressure. The product was obtained as a white solid. Yield: 5.1 g (98.1%, white solid). ¹H NMR (400 MHz, CDCl₃): δ 7.05 (d, 4H, J=8.1 Hz), 6.95 (d, 4H, J=8.2 Hz), 6.75 (s, 2H), 2.31 (s, 6H), 2.28 (s, 6H).

Preparation of Intermediate 305

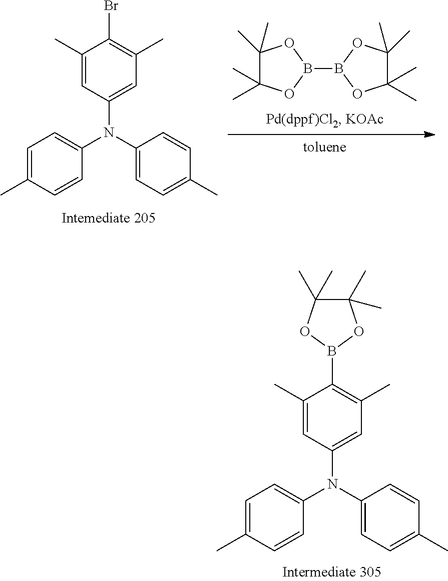

A mixture of 4-bromo-3,5-dimethyl-N,N-di-p-tolylaniline (Intermediate 205) (0.5 g, 1.31 mmol), bis(pinacolato)diboron (0.66 g, 2.60 mmol), Pd(dppf)Cl₂ (190 mg, 0.26 mmol) and KOAc (0.39 g, 3.94 mmol) were suspended in 25 mL dry DMSO. The suspension was heated to 80° C. and maintained overnight. Distilled water was added to the solution. The crude product was extracted with EtOAc/H₂O. The product was obtained as white flakes by column chromatography in SiO₂ with hexane: ethyl acetate=20:1 as the eluent. Yield: 385 mg (68.5%, white solid). ¹H NMR (400 MHz, CDCl₃): δ 7.02 (d, 4H, J=8.0 Hz), 6.94 (d, 4H, J=8.1 Hz), 6.61 (s, 2H), 2.29 (s, 12H), 1.36(s, 12H).

Preparation of Intermediate 405

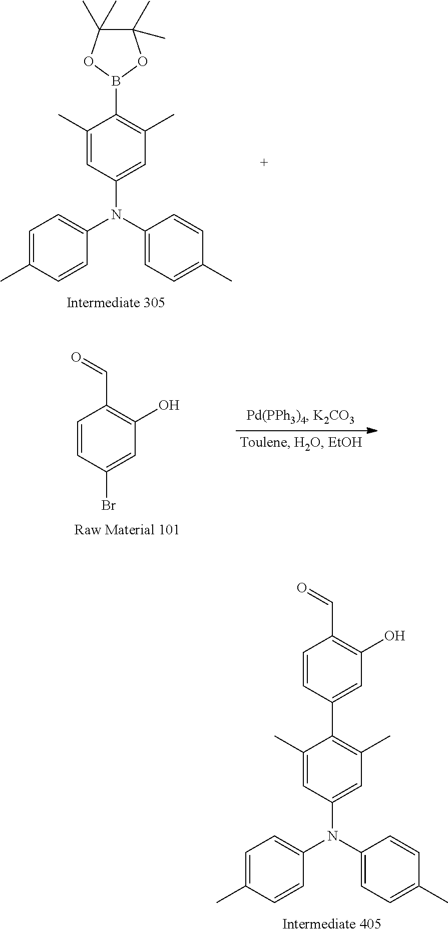

3,5-dimethyl-4-(4,4,5,5-tetramethyl-1,3,2-dioxaborolan-2-yl)-N,N-di-p-tolylaniline (Intermediate 305) (743 mg, 1.74 mmol), 4-bromo-2-hydroxybenzaldehyde (Raw material 101) (322 mg, 1.60 mmol), Pd(PPh₃)₄ (141 mg, 8 mol %) and potassium carbonate (0.49 g, 3.52 mmol) were refluxed in a degassed mixture of toluene/H₂O/EtOH (20 ml/10 ml/5 ml) under an inert atmosphere and maintained overnight, after which solvents were removed. Dilute hydrochloric acid (1M) was added to the solution. The crude product was extracted with CH₂Cl₂/H₂O. The product was obtained as white flakes by column chromatography in SiO₂ with hexane: ethyl acetate=10:1 as the eluent. Yield: 560 mg (76.4%, yellow solid). ¹H NMR (300 MHz, CDCl₃): δ 11.11 (s, 1H), 9.93 (s, 1H), 7.60 (d, 1H, J=8.3 Hz), 7.02-7.11 (m, 8H), 6.84-6.87 (m, 2H), 6.77 (s, 2H), 2.33 (s, 6H), 1.94 (s, 6H).

Preparation of Intermediate 605

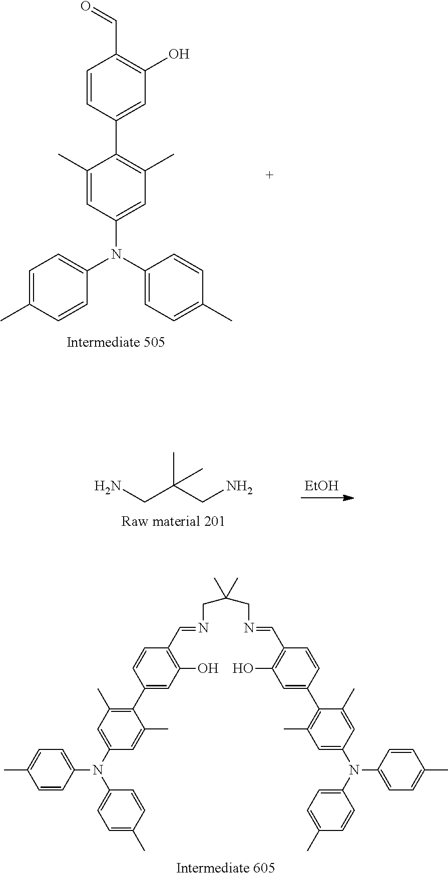

To a solution of salicylaldehyde (Intermediate 505) (600 mg, 1.42 mmol) dissolved in 15 mL ethanol, 2,2-dimethylpropane-1,3-diamine (Raw material 201) (72 mg, 0.71 mmol) in 1 mL ethanol was added dropwise. The solution was heated and the mixture refluxed overnight. The solution was concentrated by rotary evaporation. Hexane was added to precipitate the solids. The solids were filtered, washed with hexane, and used without further purification.

The procedure was similar to that of L1 except 4′-(di-p-tolylamino)-3-hydroxy-2′,6′-dimethyl[1,1′-biphenyl]-4-carbaldehyde (P7) (600 mg, 1.42 mmol) was used instead of salicylaldehyde. Yield: 555 mg (85.8%, light yellow solid). ¹H NMR (500 MHz, CDCl₃): δ 13.62 (s, 2H), 8.40 (s, 2H), 7.31 (d, 2H, J=8.0 Hz), 7.07 (d, 8H, J=8.0 Hz), 7.03 (d, 8H, J=8.5 Hz), 6.84 (s, 2H), 6.75 (s, 4H), 6.71 (d, 2H, J=8.0 Hz), 3.54 (s, 4H), 2.32 (s, 12H), 1.95 (s, 12H), 1.12 (s, 6H).

Preparation of Emitter 105

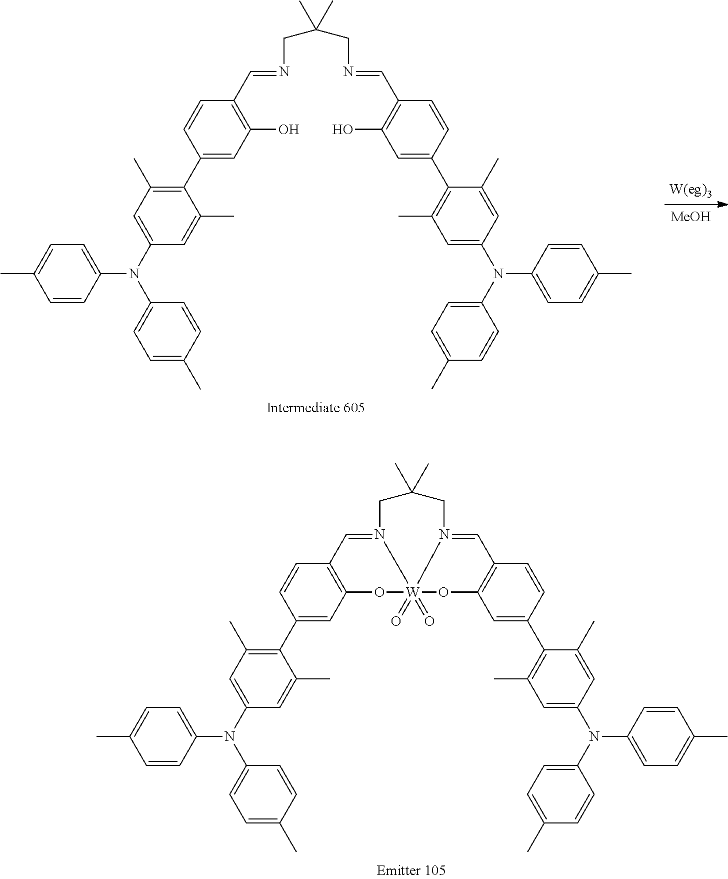

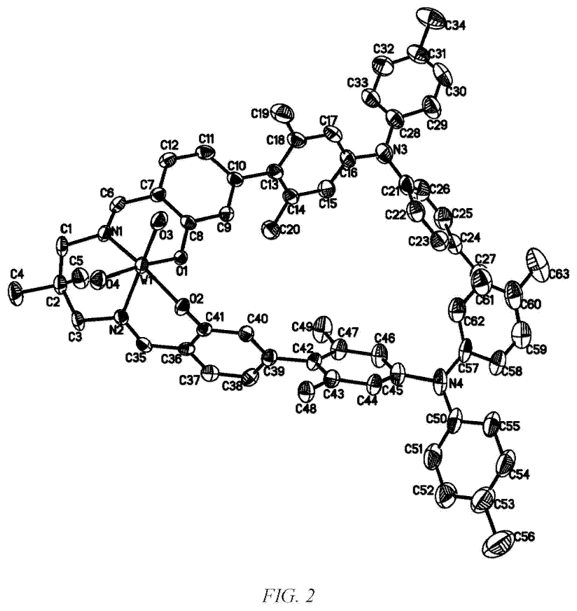

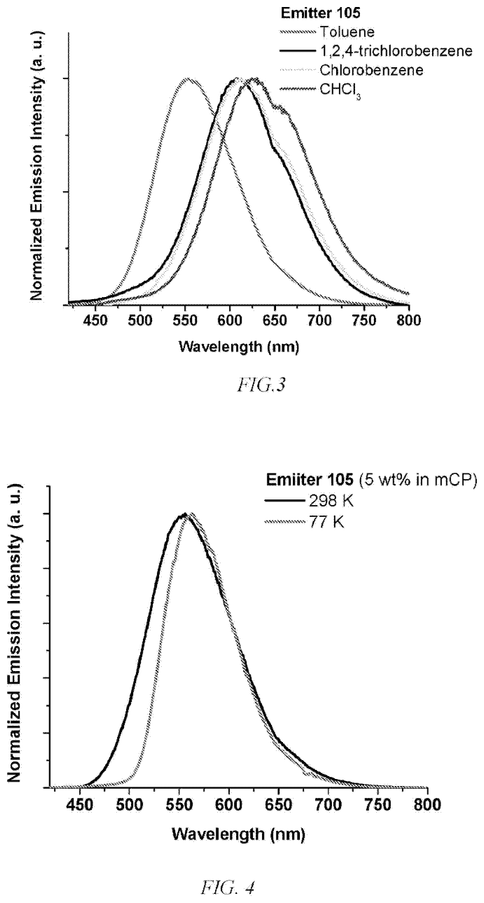

To a mixture of Intermediate 605 (100 mg, 0.11 mmol) suspended or dissolved in 20 mL methanol, W(eg)₃ (40 mg, 0.11 mmol) was added. The mixture was heated and refluxed overnight. Solvents were removed by rotary evaporation. Subsequent column chromatography with dichloromethane/ethyl acetate (4:1) yielded the product. Yield: 69 mg (55.8%, yellow solid). HR—MS (+ESI) m/z: 1123.4309 [M+H]⁺ (calcd. 1123.4359). Selected IR (KBr, ν cm⁻¹): 927.76 (W═O), 887.26 (W═O). ¹H NMR (500 MHz, CDCl₃): δ 8.21 (s, 1H, J_{H-W}=11.0 Hz), 8.10 (s, 1H), 7.42 (d, 1H, J=8.0 Hz), 7.33 (d, 1H, J=8.0 Hz), 7.07-7.09 (m, 4H), 7.03 (d, 8H, J=8.0 Hz), 6.95-6.97 (m, 5H), 6.83 (dd, 1H, J=8.0 Hz and 1.5 Hz), 6.75-6.76 (m, 2H), 6.68 (d, 2H, J=12.0 Hz), 6.58 (dd, 1H, J=8.0 Hz and 1.5 Hz), 6.46 (s, 1H), 4.92 (d, 1H, J=11.5 Hz), 4.28 (d, 1H, J=12.5 Hz), 3.77 (d, 1H, J=11.5 Hz), 3.47 (d, 1H, J=13.0 Hz), 2.31 (s, 6H), 2.29 (s, 6H), 1.95 (s, 3H), 1.93 (s, 3H), 1.92 (s, 3H), 1.91 (s, 3H), 1.20 (s, 3H), 0.86 (s, 3H). ¹³C{¹H} NMR (125 MHz, CDCl₃): δ 168.3, 163.7, 160.5, 152.3, 148.9, 147.2, 147.1, 145.4, 145.3, 136.4, 136.3, 136.2, 135.7, 134.3, 134.2, 133.2, 133.0, 132.2, 129.8, 129.7(9), 124.7, 124.6, 122.8, 122.1, 121.8, 121.6, 121.5, 121.4(5), 121.4, 121.1, 120.8, 120.6, 72.8, 60.4, 37.8, 26.1, 24.1, 21.0, 20.8, 20.7, 14.2. X-ray diffraction data is tabulated in Tables 3-5, below. The crystal structure of Emitter 105 is shown in FIG. 2. The photoluminescence (PL) spectra of Emitter 105 in various solvents is shown in FIG. 3. The PL spectra of a thin film sample of Emitter 105 at 298 K and 77 K is shown in FIG. 4.

Preparation of Emitter 101

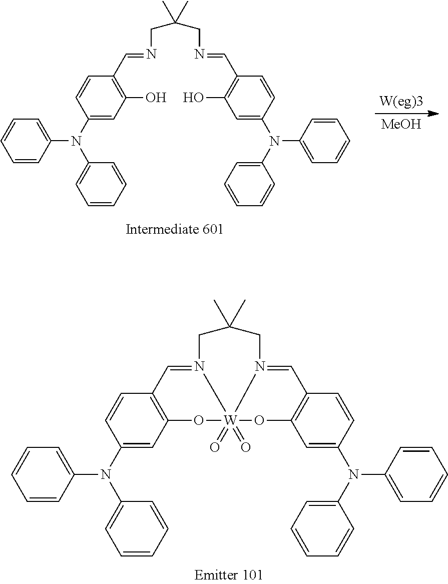

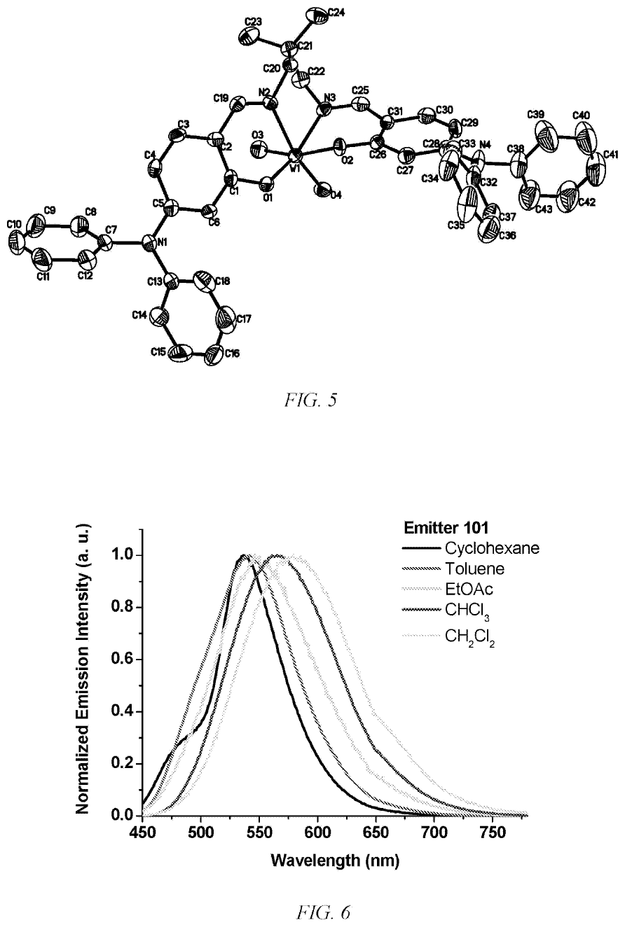

The procedure was similar to that of Emitter 105 except with the use of Intermediate 601 (86 mg, 0.13 mmol) in place of Intermediate 605. Yield: 79 mg (69.0%, yellow solid). HR—MS (+ESI) m/z: 881.2433 [M+Na]⁺ (calcd. 881.2300). Selected IR (KBr, ν cm⁻¹): 933.55 (W═O), 893.04 (W═O). ¹H NMR (500 MHz, CDCl₃): δ 7.93 (t, 1H, J=5.0 Hz), 7.85 (s, 1H), 7.27-7.33 (m, 9H), 7.18 (d, 4H, J=7.5 Hz), 7.05-7.16 (m, 9H), 6.51 (d, 1H, J=2.0 Hz), 6.49 (dd, 1H, J=8.5 Hz and 2.5 Hz), 6.30 (dd, 1H, J=9.0 Hz and 2.0 Hz), 6.16 (d, 1H, J=2.0 Hz), 4.71 (d, 1H, J=11.5 Hz), 3.84 (d, 1H, J=12.5 Hz), 3.67 (d, 1H, J=11.5 Hz), 3.30 (d, 1H, J=12.5 Hz), 1.13 (s, 3H), 0.83 (s, 3H); ¹³C{¹H} NMR (150 MHz, CDCl₃): δ 169.9, 165.5, 165.4(7), 162.4, 162.3, 161.2, 156.8, 154.0, 146.1, 145.5, 134.5, 134.4(9), 134.0, 133.9(9), 129.6, 129.5(5), 127.4, 127.3, 126.4, 125.6, 124.9, 116.6, 116.1, 112.9, 111.2, 110.2, 107.3, 75.9, 72.0, 37.6, 25.9, 24.9. X-ray diffraction data is tabulated in Tables 3-5, below. The crystal structure of Emitter 101 is shown in FIG. 5. The photoluminescence (PL) spectra of Emitter 101 in various solvents is shown in FIG. 6.

TABLE 3
X-ray diffraction data of Emitter 101 and 105

| Emitter | 101 | 105 |
|---|---|---|
| Empirical formula | C₄₃H₃₈N₄O₄W•C₂H₆O | C₆₃H₆₂N₄O₄W•2(CH₂Cl₂₎ |
| Formula weight | 904.69 | 1292.86 |
| Temperature, K | 250 | 200 |
| Crystal system | monoclinic | Triclinic |
| Space group | P2₁/n | P1-bar |
| a, Å | 11.3816 (11) | 12.174 (10) |
| b, Å | 14.4219 (12) | 16.105 (13) |
| c, Å | 23.905 (2) | 18.151 (16) |
| α, ° | 90.00 | 64.931 (15) |
| β, ° | 92.530 (3) | 89.115 (16) |
| γ ,° | 90.00 | 77.360 (16) |
| V, Å³ | 3920.0 (6) | 3133 (4) |
| Z | 4 | 2 |
| D_{c}, g cm⁻³ | 1.533 | 1.370 |
| μ, mm⁻¹ | 3.00 | 2.06 |
| F(000) | 1824 | 1316 |
| No. of reflections | 36279 | 85173 |
| No. of | 6932 | 11071 |
| independent | | |
| reflections | | |
| GoF | 1.06 | 1.09 |
| Rᵢₙₜ | 0.068 | 0.061 |
| R₁^{[a]}, wR₂^{[b]} | 0.042, 0.081 | 0.037, 0.086 |
| (I > 2(I)) | | |

^{[a]}R₁ = Σ||Fₒ| − |F_{c}||/Σ|Fₒ|.
^{[b]}wR₂ = [Σw(|Fo²| − |F_{c}²|)²/Σw|Fo²|²]^{1/2}.

TABLE 4
Selected bond lengths (Å) and bond angles
(°) of Emitter 101 and 105

| Bond Length (Å) | 101 | Bond Length (Å) | 105 |
|---|---|---|---|
| W(1)—O(1) | 1.938 (4) | W(1)—O(1) | 2.068 (3) |
| W(1)—O(2) | 2.088 (4) | W(1)—O(2) | 1.941 (3) |
| W(1)—O(3) | 1.730 (4) | W(1)—O(3) | 1.730 (3) |
| W(1)—O(4) | 1.722 (4) | W(1)—O(4) | 1.746 (3) |
| W(1)—N(1) | 2.296 (4) | W(1)—N(1) | 2.136 (3) |
| W(1)—N(2) | 2.134 (5) | W(1)—N(2) | 2.312 (4) |

TABLE 5
Selected bond lengths (Å) and bond angles
(°) of Emitter 101 and 105.

| | | |
|---|---|---|
| Bond Angle (°) | 101 | 105 |

| | | | | |
|---|---|---|---|---|
| O(1)—W(1)—O(2) | 87.66 | (15) | 82.02 | (12) |
| O(3)—W(1)—O(4) | 103.43 | (19) | 103.18 | (15) |

| | | | |
|---|---|---|---|
| N(1)—W(1)—N(2) | — | 79.61 | (13) |

| N(3)—W(1)—N(2) | 76.95 | (16) | — | |
|---|---|---|---|---|
| O(1)—W(1)—O(3) | 97.78 | (18) | 92.18 | (14) |
| O(1)—W(1)—O(4) | 104.03 | (16) | 162.60 | (13) |
| O(2)—W(1)—O(3) | 164.33 | (16) | 103.61 | (13) |
| O(2)—W(1)—O(4) | 89.36 | (17) | 101.90 | (14) |

| | | | |
|---|---|---|---|
| O(1)—W(1)—N(1) | — | 78.97 | (13) |

| | | | | |
|---|---|---|---|---|
| O(1)—W(1)—N(2) | 81.74 | (15) | 80.08 | (13) |

| | | | |
|---|---|---|---|
| O(2)—W(1)—N(1) | — | 154.44 | (13) |

| | | | | |
|---|---|---|---|---|
| O(2)—W(1)—N(2) | 79.65 | (15) | 80.41 | (12) |

| | | | |
|---|---|---|---|
| O(3)—W(1)—N(3) | 89.87 | (18) | — |
| O(4)—W(1)—N(3) | 95.26 | (17) | — |
| O(1)—W(1)—N(3) | 156.88 | (16) | — |

| | | | |
|---|---|---|---|
| N(1)—W(1)—O(3) | — | 94.08 | (14) |

| | | | |
|---|---|---|---|
| O(2)—W(1)—N(3) | 79.84 | (16) | — |

| | | | |
|---|---|---|---|
| N(1)—W(1)—O(4) | — | 91.66 | (14) |

| | | | | |
|---|---|---|---|---|
| N(2)—W(1)—O(3) | 86.56 | (17) | 170.79 | (13) |
| N(2)—W(1)—O(4) | 167.45 | (17) | 83.85 | (14) |

Preparation of Emitter 102

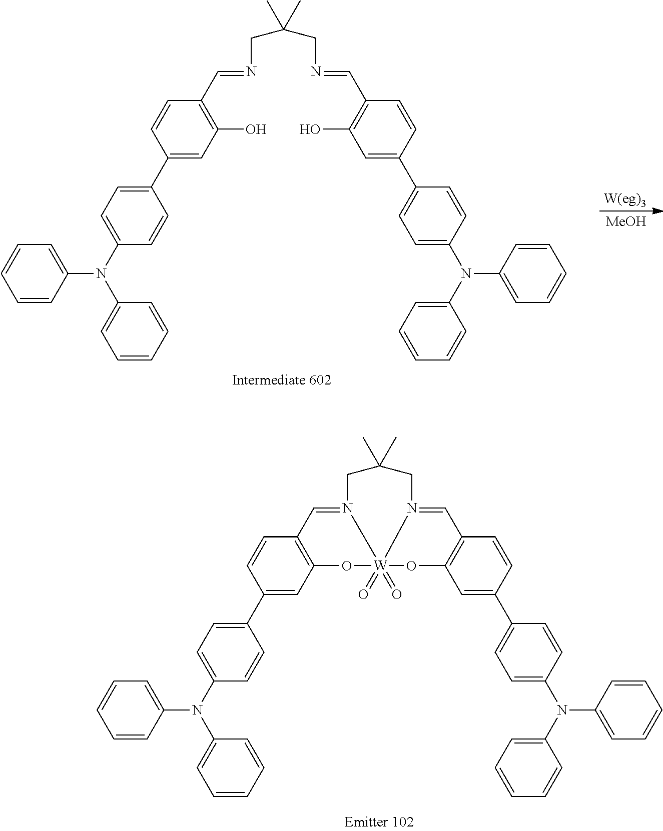

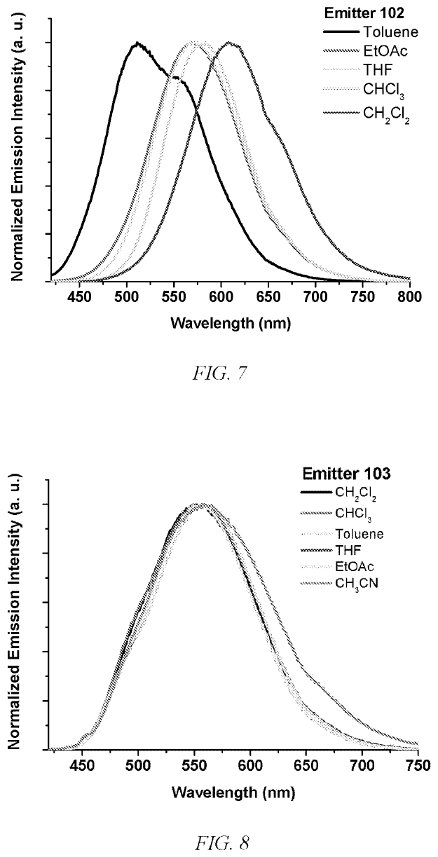

The procedure was similar to that of Emitter 105 except with the use of Intermediate 602 (69 mg, 0.09 mmol) in place of Intermediate 605. Yield: 56 mg (61.6%, yellow solid). HR—MS (+ESI) m/z: 1033.2933 [M+Na]⁺ (calcd. 1033.2926). Selected IR (KBr, ν cm⁻¹): 927.76 (W═O), 887.26 (W═O). ¹H NMR (500 MHz, CDCl₃): δ 8.18 (t, 1H, J=5.5 Hz), 8.06 (s, 1H), 7.57 (d, 2H, J=8.5 Hz), 7.39-7.42 (m, 3H), 7.34-7.36 (m, 2H), 7.24-7.30 (m, 10H), 7.08-7.16 (m, 11H), 7.02-7.07 (m, 4H), 6.97 (dd, 1H, J=7.0 and 1.0 Hz), 6.84 (s, 1H), 4.90 (d, 1H, J=11.0 Hz), 4.34 (d, 1H, J=12.5 Hz), 3.74 (d, 1H, J=11.0 Hz), 3.43 (d, 1H, J=13.0 Hz), 1.17 (s, 3H), 0.81 (s, 3H). ¹³C{¹H} NMR (150 MHz, CDCl₃): δ 168.5, 168.0, 163.4, 160.6, 150.6, 148.4(3), 148.4(1), 147.4, 147.3, 147.2, 133.8, 133.0, 132.6, 129.4, 129.3(7), 128.0, 127.9, 125.0, 124.9, 123.4(3), 123.4(1), 123.1, 122.7, 121.5, 121.0, 119.1, 118.2, 117.9, 117.3, 73.1, 37.9, 26.1, 23.7. The photoluminescence (PL) spectra of Emitter 102 in various solvents is shown in FIG. 7.

Preparation of Emitter 103

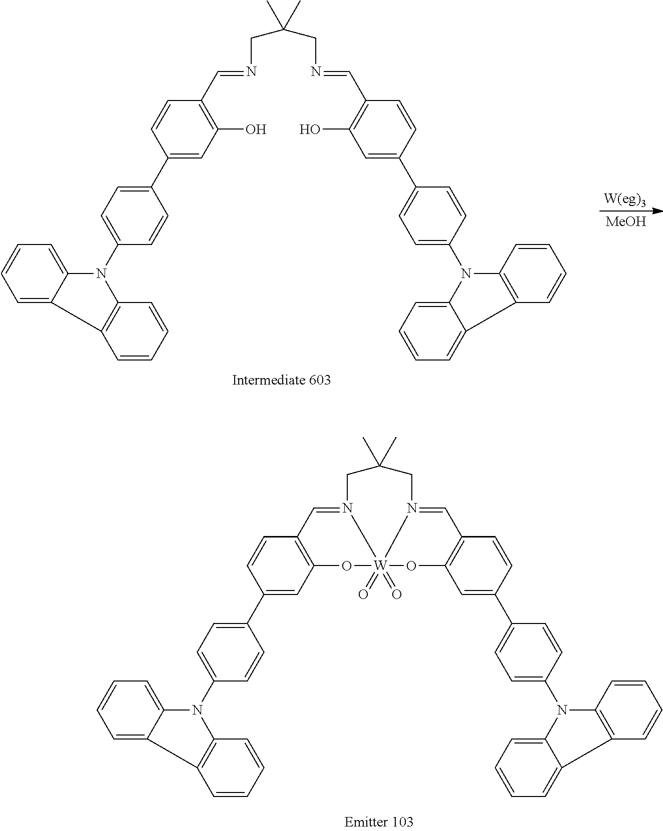

The procedure was similar to that of Emitter 105 except with the use of Intermediate 603 (86 mg, 0.11 mmol) in place of Intermediate 605. Yield: 46 mg (42.1%, yellow solid). HR—MS (+ESI) m/z: 1007.2744 [M+H]⁺ (calcd. 1007.2794). Selected IR (KBr, ν cm⁻¹): 933.55 (W═O), 896.90 (W═O). ¹H NMR (500 MHz, CDCl₃): δ 8.28 (s, 1H, J_{H-W}=11.0 Hz), 8.12-8.16 (m, 5H), 7.94 (d, 2H, J=8.0 Hz), 7.77 (d, 2H, J=8.5 Hz), 7.70 (d, 2H, J=8.5 Hz), 7.60 (d, 2H, J=8.5 Hz), 7.53-7.54 (m, 2H), 7.48 (t, 3H, J=8.5 Hz), 7.37-7.44 (m, 7H), 7.27-7.31 (m, 4H), 7.09 (dd, 1H, J=8.5 and 1.0 Hz), 7.01 (s, 1H), 4.96 (d, 1H, J=11.0 Hz), 4.43 (d, 1H, J=12.0 Hz), 3.81 (d, 1H, J=11.0 Hz), 3.50 (d, 1H, J=12.5 Hz), 1.22 (s, 3H), 0.86 (s, 3H). ¹³C{¹H} NMR (125 MHz, CDCl₃): 6 168.5, 168.3, 163.6, 160.6, 150.1, 146.8, 140.7, 140.6, 138.8, 128.3, 138.1, 138.0(7), 134.0, 128.7, 128.6(6), 127.4, 127.2, 126.1, 126.0, 123.5, 123.4(9), 122.2, 121.6, 120.3, 120.2, 120.1, 119.7, 119.3, 118.8, 117.7, 109.8, 109.7(7), 73.2, 37.9, 26.1, 23.6. The photoluminescence (PL) spectra of Emitter 103 in various solvents is shown in FIG. 8.

Photophysical data for the Emitters 101-103, and 105 is provided below in Table 6.

TABLE 6
Photophysical Data of Emitters 101-103, and 105

| | | λ_{abs} [nm] | | | | |
|---|---|---|---|---|---|---|
| Emitter | Medium^{[a][b]} | (ε [10³ mol⁻¹ dm³ cm⁻¹]) | λₑₘ [nm] | τ [μs] | kᵣ[10³ s⁻¹]) | Φₑₘ^{[c]} |
| 101 | CH₂Cl₂ | 291 (22.8), 404 (32.9) | 579 | 8.0 | 8.5 | 0.068 |
| | Cyclohexane | 294 (22.7), 387 (31.9) | 482(sh), 537 | 89.7 | 1.2 | 0.11 |
| | Toluene | 299 (sh, 29.0), 392 | 541 | 51.9 | 1.8 | 0.092 |
| | | (33.6), 421 (28.4) | | | | |
| | EtOAc | 291 (24.3), 387 (31.7) | 546 | 22.0 | 0.8 | 0.018 |
| | CHCl₃ | 294 (24.5), 410 (36.0) | 565 | 28.2 | 6.0 | 0.17 |
| | CH₃CN | 346 (sh, 20.8), 392 (29.6) | 588 | 0.43 | | weak |
| | CH₃OH | 288 (24.2), 349 (sh, | weak | | | weak |
| | | 21.5), 410 (29.7) | | | | |
| | Solid | | 535 | 0.66 | | |
| | Solid (77 K) | | 556 | 902.2 | | |
| | Glassy | | 552 | 2006.9 | | |
| | 5% in mCP | | 546 | 252.6 | 1.9 | 0.48 |
| | 5% in PMMA | | 548 | 44.4 | 2.0 | 0.09 |
| 102 | CH₂Cl₂ | 297 (49.8), 407 (38.4) | 608 | 4.6 | 23.9 | 0.11 |
| | CHCl₃ | 299 (45.2), 410 (36.7) | 583 | 22.1 | 12.7 | 0.28 |
| | THF | 292 (49.7), 392 (42.9) | 572 | 117.8 | 2.3 | 0.27 |
| | EtOAc | 297 (sh, 56.3), 402 (41.9) | 570 | 45.6 | 2.4 | 0.11 |
| | Toluene | 297 (sh, 55.2), 402 (40.8) | 510, 552(sh) | 67.6 | 0.6 | 0.04 |
| | Solid | | 539 | 1.1 | | |
| | Solid (77 K) | | 525(sh), 588 | 6.7; 1285.1 | | |
| | Glassy | | 563(sh), 594 | 3353.8 | | |
| | 5% in mCP | | 567 | 227.8 | 2.2 | 0.49 |
| | 5% in PMMA | | 575 | 49.9 | 3.4 | 0.17 |
| 103 | CH₂Cl₂ | 261 (57.1), 285 (45.9), | 553 | 74.9 | 1.7 | 0.13 |
| | | 292 (49.8), 327 (30.4), | | | | |
| | | 341 (31.9), 365 (25.0), | | | | |
| | | 420 (10.6) | | | | |
| | CHCl₃ | 286 (50.1), 293 (54.2), | 555 | 98.7 | 1.5 | 0.15 |
| | | 315 (29.7), 328 (31.7), | | | | |
| | | 342 (32.7), 368 (25.9), | | | | |
| | | 420 (11.4) | | | | |
| | Toluene | 293 (64.0), 327 (32.5), | 560 | 97.3 | 2.1 | 0.21 |
| | | 342 (34.2), 368 (28.1), | | | | |
| | | 420 (11.3) | | | | |
| | THF | 283 (49.8), 292 (55.2), | 556 | 82.0 | 1.3 | 0.11 |
| | | 327 (35.6), 341 (39.2), | | | | |
| | | 415 (10.2) | | | | |
| | EtOAc | 283 (49.1), 291 (54.3), | 556 | 99.0 | 1.3 | 0.13 |
| | | 326 (36.2), 340 (39.8), | | | | |
| | | 415 (10.1) | | | | |
| | CH₃CN | 283 (47.6), 291 (51.6), | 560 | 11.8 | 1.3 | 0.02 |
| | | 326 (35.1), 340 (37.5), | | | | |
| | | 415 (10.4) | | | | |
| | Solid | | 533 | 2.8 | | |
| | Solid (77 K) | | 561 | 440.0 | | |
| | Glassy | | 556 | 988.6 | | |
| | 5% in mCP | | 564 | 276.9 | 1.4 | 0.40 |
| | 5% in PMMA | | 562 | 51.9 | 1.3 | 0.068 |
| 105 | CHCl₃ | 305 (60.5), 406 (11.1) | 626, 659(sh) | 0.07 | 857.1 | 0.06 |
| | Toluene | 300 (67.1), 400 (11.4) | 554 | 14.7 | 38.1 | 0.56 |
| | 1,2,4- | 415 (11.2) | 609, 655(sh) | 0.37 | 729.7 | 0.27 |
| | trichlorobenzene | | | | | |
| | chlorobenzene | 306 (66.4), 400 (11.8) | 612, 658(sh) | 0.14 | 928.6 | 0.13 |
| | Solid | | 568 | 1.3 | | |
| | Solid (77 K) | | 585 | 2.3, 19.6 (5.2)^{[d]} | | |
| | Glassy | | 562 | 712.1 | | |
| | 5% in mCP | | 555 | 1.0, 7.1 (2.0)^{[d]} | 414.0^{[d]} | 0.84 |
| | 5% in mCP (77 K) | | 563 | 59.5, 683.7 (358.0)^{[d]} | | |
| | 5% in PMMA | | 567 | 1.0, 4.9 (1.4)^{[d]} | 278.6^{[d]} | 0.39 |

^{[a]}Measurements were performed at 298 K unless specified.
^{[b]}Thin-film emission measured in 5 wt % poly(methyl methacrylate) (PMMA) film or 1,3-Bis(N-carbazolyl)benzene (mCP) film.
^{[c]}All emission quantum yields (Φ) were measured with a Hamamatsu Quantaurus-QY Absolute PL quantum yields spectrometer.
^{[d]}Weighted average lifetime τₐᵥ = (A₁τ₁ + A₂τ₂)/(A₁ + A₂) for biexponential decay.’

TABLE 7
Summary of Photophysical Data of Emitters 101-103, and 105

| | | | | | Thin-film | | |
|---|---|---|---|---|---|---|---|
| | | Solution | Φₑₘ in | | 5 wt % in mCP | Φₑₘ in | |
| | | λₘₐₓ/nm; | solution | kᵣ/ | λₘₐₓ/nm; | film | kᵣ/ |
| Complex | Solvent | τ/μs | (%) | 10³ s⁻¹ | τ/μs | (%) | 10³ s⁻¹ |
| 101 | CH₂Cl₂ | 565; 28.2 | 17% | 6.0 | 546; 252.6 | 48% | 1.9 |
| 102 | CHCl₃ | 583; 22.1 | 28% | 12.7 | 567; 227.8 | 49% | 2.2 |
| 103 | CHCl₃ | 555; 98.7 | 15% | 1.5 | 564; 276.9 | 40% | 1.4 |
| 105 | Toluene | 554; 14.7 | 56% | 38.1 | 555; 2.0^{[a]} | 84% | 414.0^{[a]} |

^{[a]}Biexponential decay: lifetime τ of 7 is a weighted average lifetime τₐᵥ = (A₁τ₁ + A₂τ₂)/(A₁ + A₂). kr in thin-film calculated from τₐᵥ.

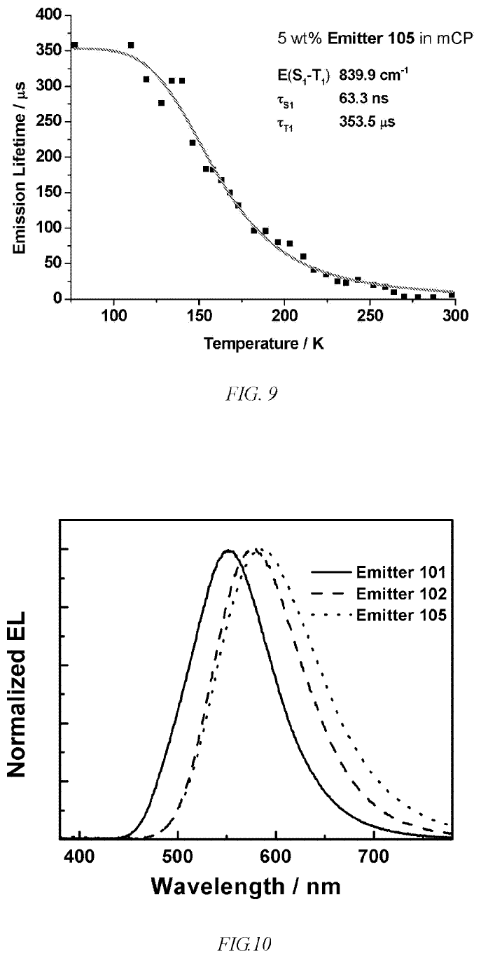

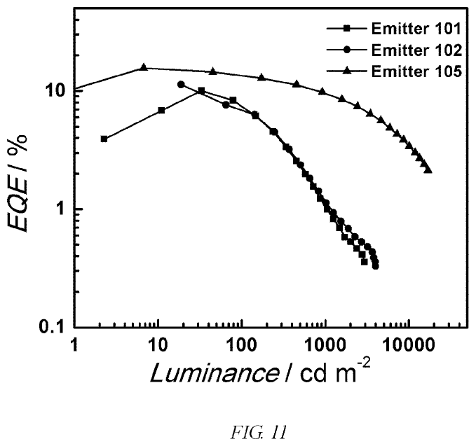

Emitter 105 features an exceptionally high radiative decay rate of 414×10³ s⁻¹ and a short emission lifetime of 2 μs (weighted average) in mCP film at 298K. The emission spectra of Emitter 105 of 5% w/w in mCP at 298K and 77K is shown in FIG. 4 where a red shift of the emission maximum by 8 nm at 77K occurs. Significantly, the variable-temperature emission lifetime measurement depicted in FIG. 9 suggests an energy separation of 840 cm⁻¹ between the S₁ and T₁ states, which is an energy gap small enough (less than 1500 cm⁻¹) to allow efficient reverse intersystem crossing to take place at ambient temperature via thermal equilibration. These characteristic spectral parameters clearly evidenced the TADF behaviour of Emitter 105.

OLED Fabrication Procedures

Materials: PEDOT:PSS [poly(3,4-ethylenedioxythiophene):poly(styrene sulfonic acid)] (Clevios P AI 4083) was purchased from Heraeus, PVK (polyvinylcarbazole) from Sigma-Aldrich, OXD-7 [(1,3-bis[(4-tert-butylphenyl)-1,3,4-oxadiazolyl]phenylene)], and TPBi [2,2′, 2″-(1,3,5-benzinetriyl)-tris(1-phenyl-1-H-benzimidazole)] from Luminescence Technology Corp. All of the materials were used as received.

Substrate cleaning: Glass slides with pre-patterned ITO electrodes used as substrates of OLEDs were cleaned in an ultrasonic bath of Decon 90 detergent and deionized water, rinsed with deionized water, and then cleaned in sequential ultrasonic baths of deionized water, acetone, and isopropanol, and subsequently dried in an oven for 1 h.

Fabrication and characterization of devices: PEDOT:PSS were spin-coated onto the cleaned ITO-coated glass substrate and baked at 120° C. for 20 minutes to remove the residual water solvent in a clean room. Blends of emitting layer were spin-coated from chlorobenzene atop the PEDOT:PSS layer inside a N₂-filled glove box. The thickness for all EMLs was about 60 nm. Afterwards, the were annealed at 110° C. for 10 min inside the glove box and subsequently transferred into a Kurt J. Lesker SPECTROS vacuum deposition system without exposing to air. Finally, TPBi (40 nm), LiF (1.2 nm), and Al (100 nm) were deposited in sequence by thermal evaporation at a pressure of 10⁻⁸ mbar. EQE, PE, CE, and CIE coordinates were measured using a Keithley 2400 source-meter and an absolute external quantum efficiency measurement system (C9920-12, Hamamatsu Photonics). All devices were characterized at room temperature without encapsulation. EQE and power efficiency were calculated by assuming a Lambertian distribution.

Performance of OLEDs fabricated by Emitters 101, 102, and 105.

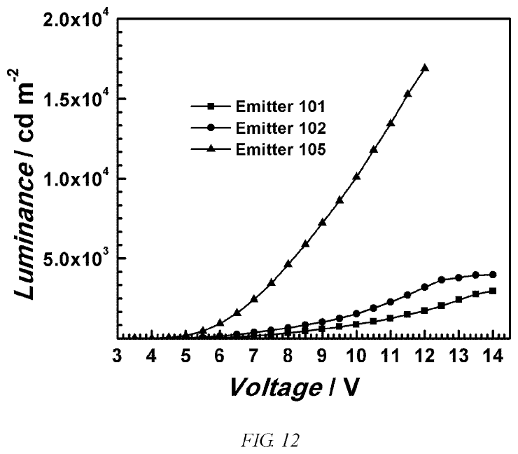

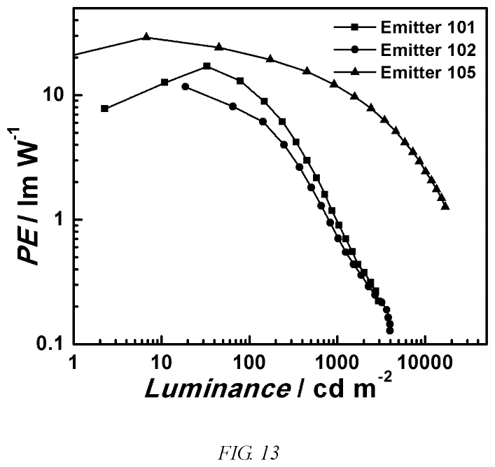

As depicted in FIG. 10, EL spectra of the device fabricated with Emitters 101, 102, and 105 display broad featureless emissions with maxima located at 554, 572, and 590 nm, respectively. EQE-luminance characteristics for Emitters 101, 102, and 105 are plotted in FIG. 11, where the maximum EQEs of 10.05, 11.32, and 15.56% are achieved at luminances of ˜30, ˜20, and ˜10 cd m⁻², respectively. An EQE of 9.7% was measured at the luminance of 1000 cd n⁻² for Emitter 105. Luminance-voltage characteristics for Emitters 101, 102, and 105 are plotted in FIG. 12. Power efficiency-luminance characteristics for Emitters 101, 102, and 105 are plotted in FIG. 13, where luminances up to 2960, 3980, and 16900 cd m⁻², respectively are realized in the devices. Key performance data for solution-processed OLED devices using Emitters 101, 102, and 105 is summarized in Table 8, below.

TABLE 8
Performance data of OLED fabricated
with Emitter 101, 102 and 105.

| | Max. | Max. Power | Max. | EQE at luminance |
|---|---|---|---|---|
| | Luminance | Efficiency | EQE | of 1000 cd m⁻² |
| Emitter | (cd m⁻²) | (cd/A) | (%) | (%) |
| 101 | 2960 | 17.0 | 10.05 | 1.0 |
| 102 | 3980 | 11.7 | 11.32 | 1.1 |
| 105 | 16900 | 29.1 | 15.56 | 9.7 |

A model complex of the structure:

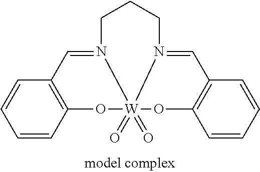

having no spacer and donor groups is compared and Emitter 101-103 and 105 in terms of Φₑₘ in mCP film, maximum CE, PE and EQE of the corresponding devices in Table 9, below. As can been seen, Emitter 101-103 and 105 exhibit superior PLQY maximum PE and/or EQE resulting from the existence of Spacer and/or Donor group(s) at the specified position.

TABLE 9
Comparison of PL and EL data between model
complex and Emitter 101-103, 105.

| | | Max. | Max. | Max |
|---|---|---|---|---|
| Emitter | Φₑₘ ^{a} | Luminance (cd) | PE (%) | EQE (%) |
| model complex | 0.22 | 1400 | / | 4.79 |
| 101 | 0.48 | 2960 | 17.0 | 10.05 |
| 102 | 0.49 | 3980 | 11.7 | 11.32 |
| 103 | 0.40 | / | / | / |
| 105 | 0.84 | 16900 | 29.1 | 15.56 |

^{a} measured in 5 wt % mCP film at 298 K.

It should be understood that the examples and embodiments described herein are for illustrative purposes only and that various modifications or changes in light thereof will be suggested to persons skilled in the art and are to be included within the spirit and purview of this application.

1. A compound having the following chemical structure: 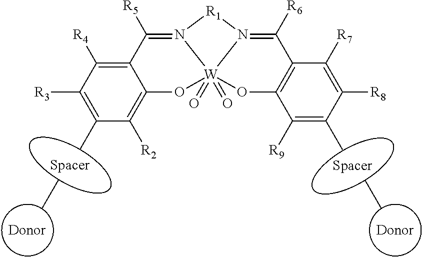
where:
W is tungsten in an oxidation state of VI;
R₁ is a connector between imine (C═N) units selected from a single bond or a bridge comprising a plurality of atoms and bonds, optionally containing heteratoms selected from —O—, and —S—, substituted or unsubstituted C₁-C₆ alkylene, substituted or unsubstituted C₃-C₁₂ cycloalkylene, C₂-C₈ alkenylene, substituted or unsubstituted C₆-C₁₀ arylene, sulfonyl, carbonyl, —CH(OH)—, —C(═O)O—, —O—C(═O)—, or 5-8 member heterocyclene group, any combination of two or more of these groups; preferably, R₁ is a connector between imine (C═N) units selected from substituted or unsubstituted C₁-C₆ alkylene, and substituted or unsubstituted C₃-C₁₂ cycloalkylene.
spacers are independently selected from a single bond, unsubstituted or substituted C₆-C₁₀ arylene or C₆-C₁₀ heteroarylene; preferably, spacers are independently selected from a single bond, and unsubstituted or substituted C₆-C₁₀ arylene; and
donors are independently selected from one or two of the following structures: 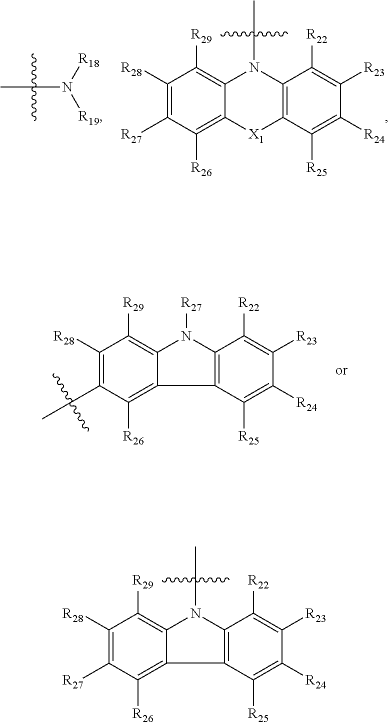
where R₁₈-R₁₉ are independently hydrogen, unsubstituted alkyl, substituted alkyl, unsubstituted cycloalkyl, substituted cycloalkyl, unsubstituted aryl, substituted aryl, acyl, unsubstituted aralkyl, unsubstituted aralkyl, styryl, aryloxycarbonyl, phenoxycarbonyl, or an alkoxycarbonyl group, where a pair of adjacent R groups of R₁₈-R₁₉ can independently form a 5-8 member heterocyclic ring; and R₂₂-R₂₉ are independently hydrogen, halogen, hydroxyl, an unsubstituted alkyl, a substituted alkyl, cycloalkyl, unsubstituted aryl, substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, or alkoxycarbonyl and X₁ is selected from CH₂, CHR, CR₂, O, S, NH, NR, PR, or SiR₂, and where R is independently hydrogen, unsubstituted alkyl, a substituted alkyl, cycloalkyl, unsubstituted aryl, substituted aryl, acyl, unsubstituted aralkyl, substituted aralkyl, or styryl;
preferably, donors are independently selected from one or two of the following structures: 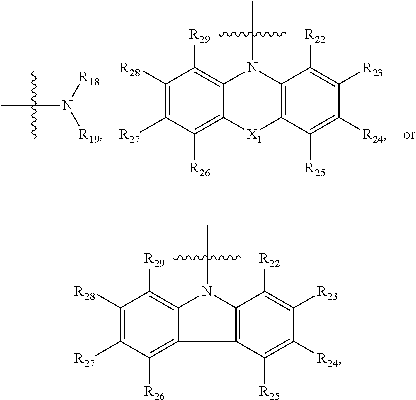
where R₁₈-R₁₉ are independently unsubstituted aryl, or substituted aryl, where a pair of adjacent R groups of R₁₈-R₁₉ can independently form a 5-8 member heterocyclic ring; and R₂₂-R₂₉ are independently hydrogen, an unsubstituted alkyl, or a substituted alkyl, and unsubstituted aryl, substituted aryl, and X₁ is selected from CH₂, CHR, CR₂, O, or S, and where R is independently unsubstituted alkyl, or a substituted alkyl; and
where R₂-R₉ are independently hydrogen, halogen, hydroxyl, unsubstituted alkyl, substituted alkyl, cycloalkyl, unsubstituted aryl, substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, or alkoxycarbonyl, and where any pair of adjacent R groups or substituents on the spacers separated by three or four bonds can form portions of a substituted or unsubstituted 5-8 member cycloalkyl, aryl, heterocycle, or heteroaryl ring; preferably, R₂-R₉ are independently hydrogen, or halogen.

2. The compound according to claim 1, wherein the chemical structure is: 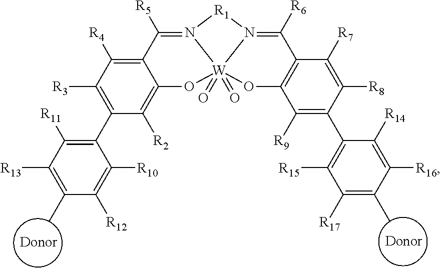
where R₁₁-R₁₇ are independently hydrogen, halogen, hydroxyl, an unsubstituted alkyl, a substituted alkyl, cycloalkyl, an unsubstituted aryl, a substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, or alkoxycarbonyl, and, optionally, one or more of R₁₁ and R₁₃, R₁₀ and R₁₂, R₁₄ and R₁₆, R₁₅ and R₁₇, and when donors are 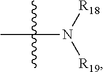
R₁₃ and R₁₈, R₁₂ and R₁₈, R₁₆ and R₁₈, R₁₇ and R₁₈ in combination is a portion of a 5-8 member ring; preferably, R₁₁-R₁₇ are independently hydrogen, an unsubstituted alkyl, a substituted alkyl, an unsubstituted aryl, a substituted aryl.

3. The compound according to claim 1, wherein R₂-R₁₉ are independently selected from hydrogen, halogen, hydroxyl, unsubstituted or substituted C₁-C₂₀ alkyl, C₄-C₂₀ cycloalkyl, unsubstituted or substituted C₆-C₁₂ aryl, C₁-C₂₀ acyl, C₁-C₂₀ alkoxy, C₁-C₂₀ acyloxy, amino, nitro, C₁-C₂₀ acylamino, C₁-C₂₀ aralkyl, cyano, C₁-C₂₀ carboxyl, thiol, styryl, C₁-C₂₀ aminocarbonyl, carbamoyl, C₁-C₂₀ aryloxycarbonyl, C₁-C₂₀ phenoxycarbonyl, and C₁-C₂₀ alkoxycarbonyl.

4. The compound according to claim 1, selected from:

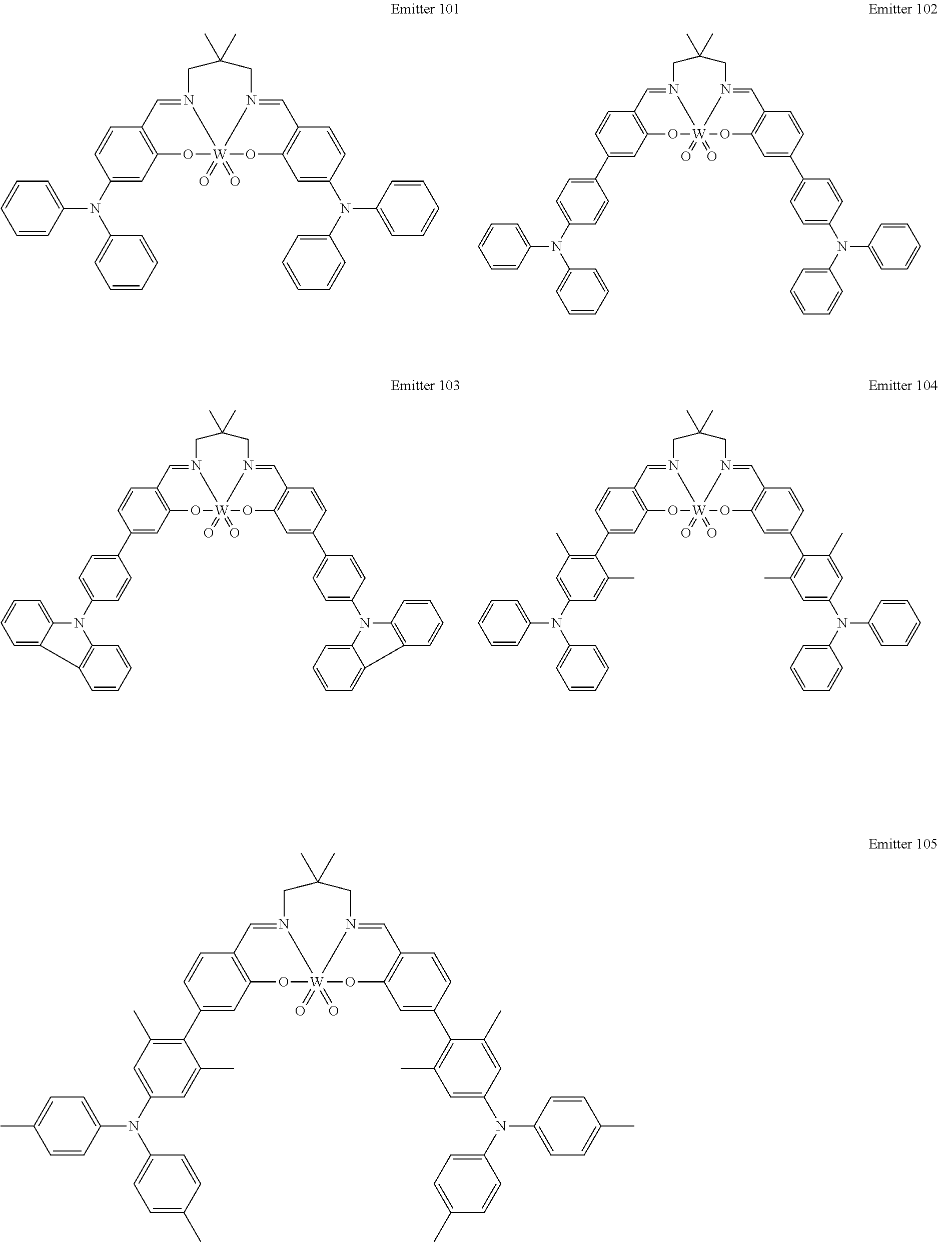

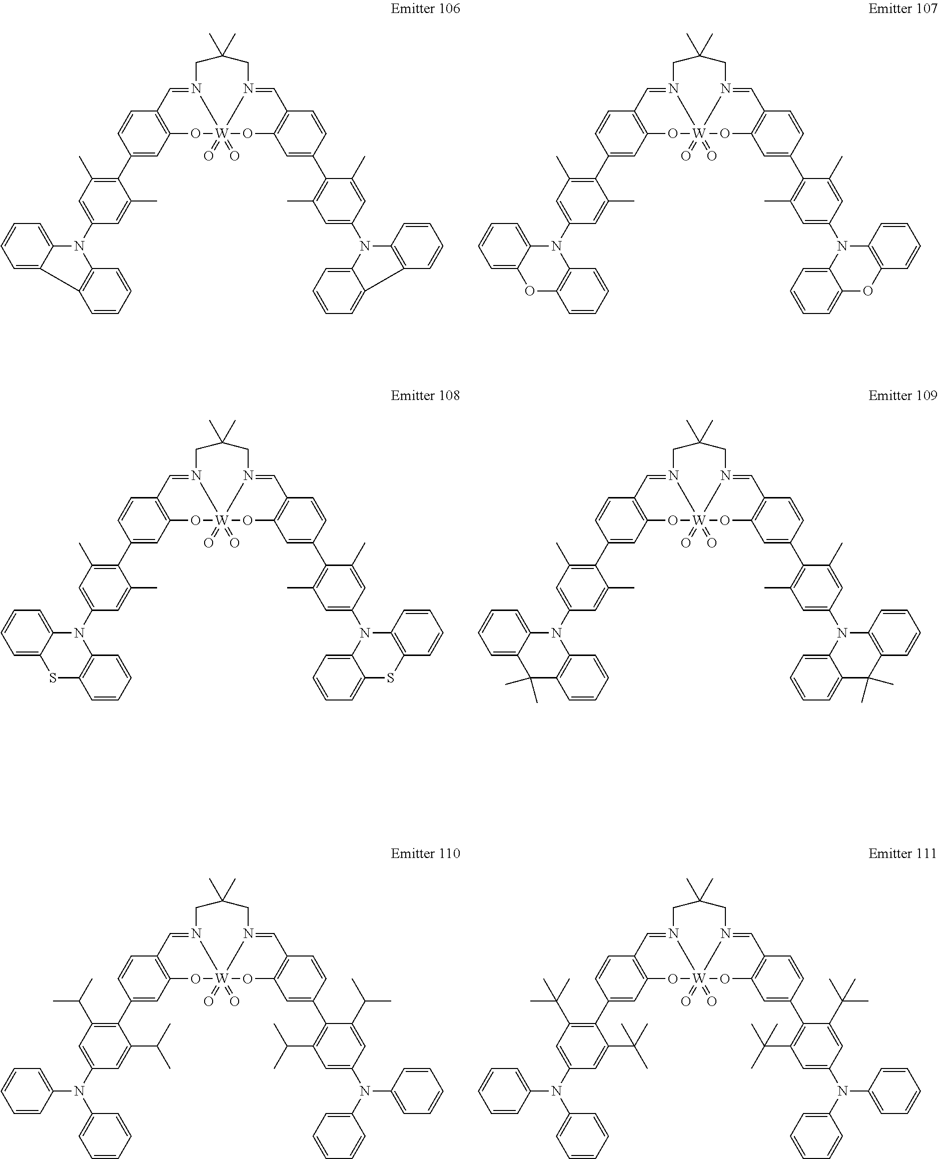

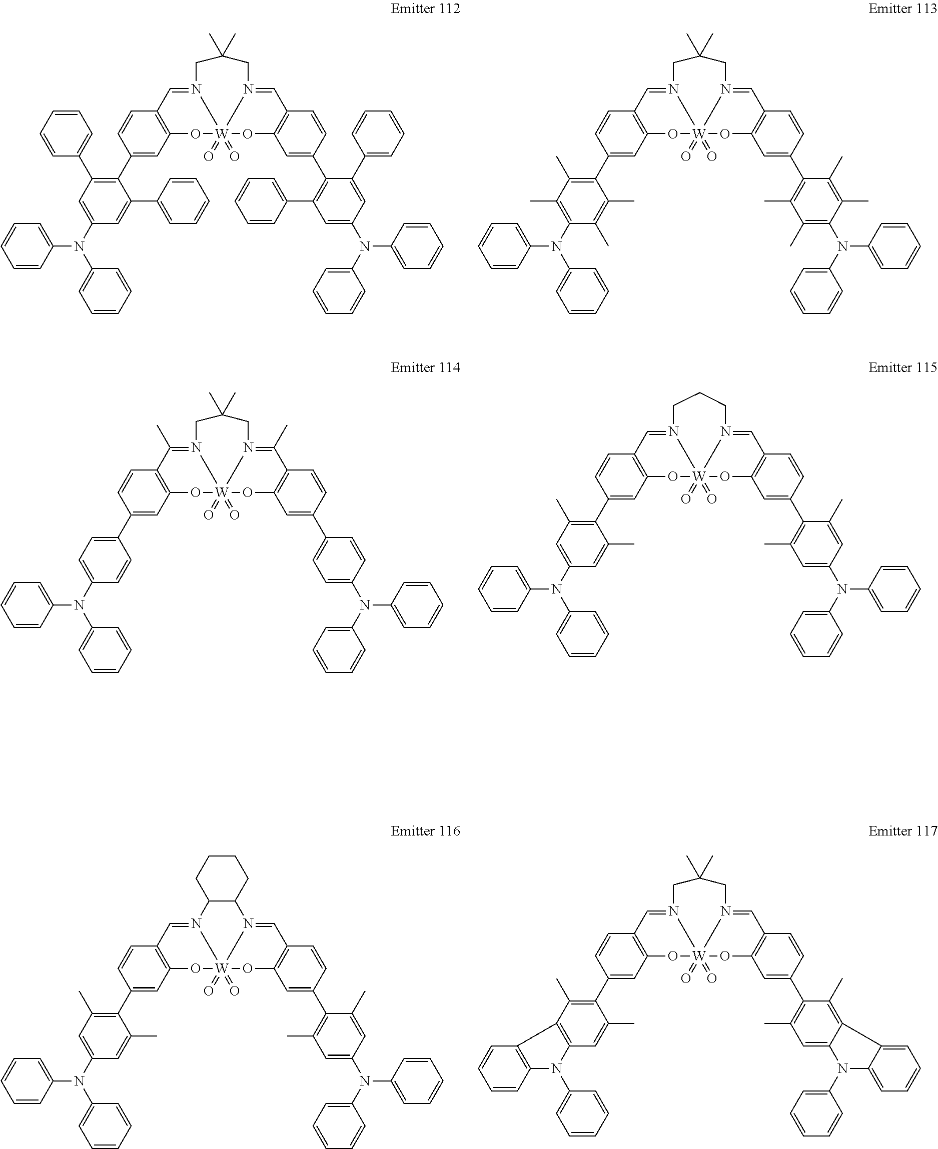

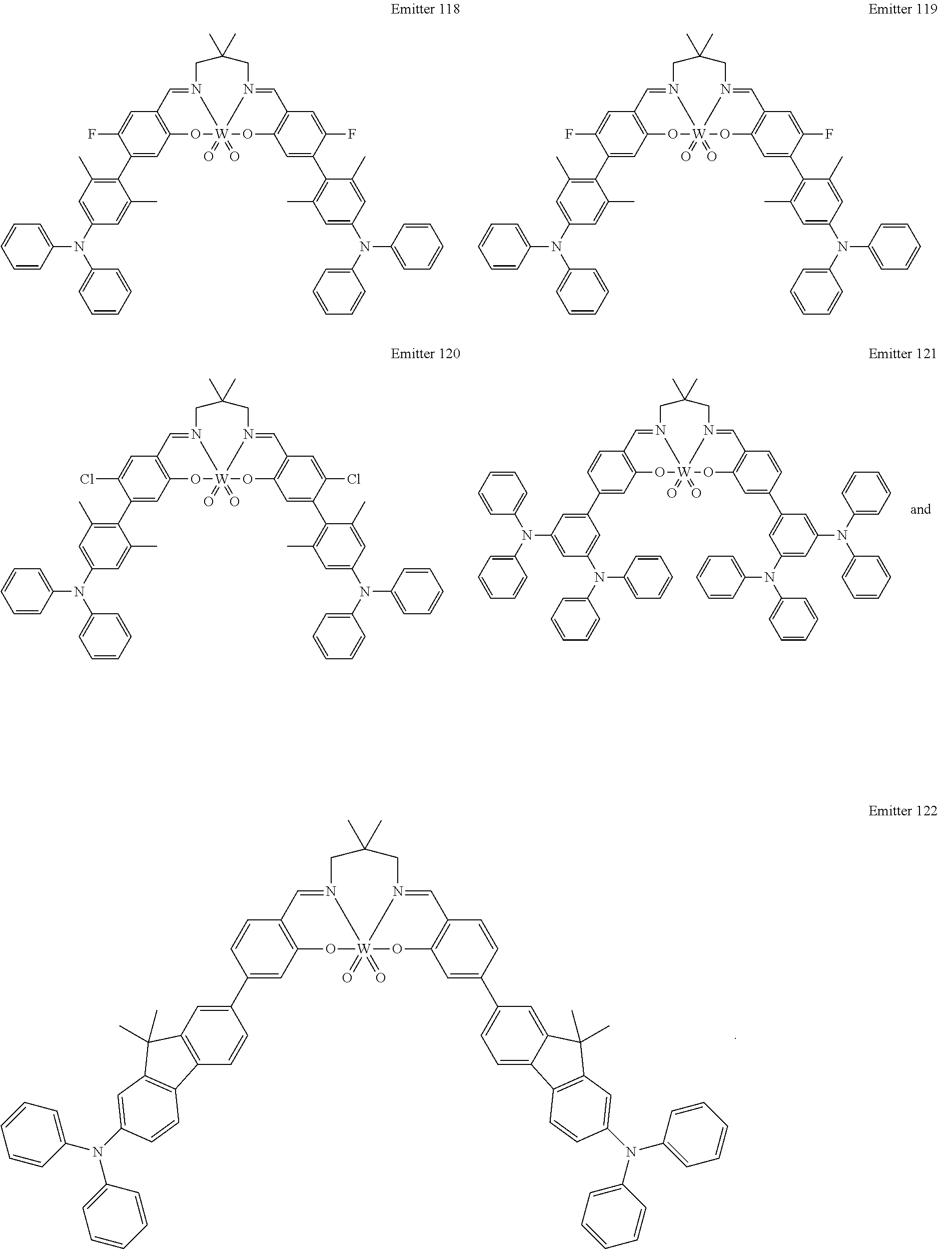

5. The compound according to claim 1, wherein the compound has thermally activated delay fluorescence.

6. The compound according to claim 1, wherein the compound has an energy separation between S₁ and T₁ states below 1500 cm⁻¹.

7. A tetradentate ligand of the structure: 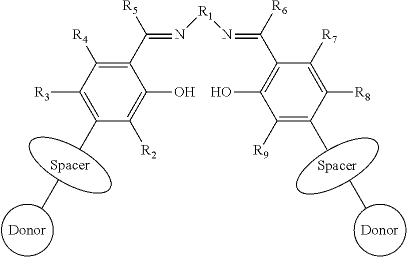
where:
R₁ is a connector between imine (C═N) units selected from a single bond or a bridge comprising a plurality of atoms and bonds, optionally containing heteratoms selected from —O—, and —S—, substituted or unsubstituted C₁-C₆ alkylene, substituted or unsubstituted C₃-C₁₂ cycloalkylene, C₂-C₈ alkenylene, substituted or unsubstituted C₆-C₁₀ arylene, sulfonyl, carbonyl, —CH(OH)—, —C(═O)O—, —O—C(═O)—, or 5-8 member heterocyclene group, or any combination of two or more of these groups;
spacers are independently selected from a single bond, unsubstituted or substituted C₆-C₁₀ arylene or C₆-C₁₀ heteroarylene; and
donors are independently selected from one or two of the following structures: 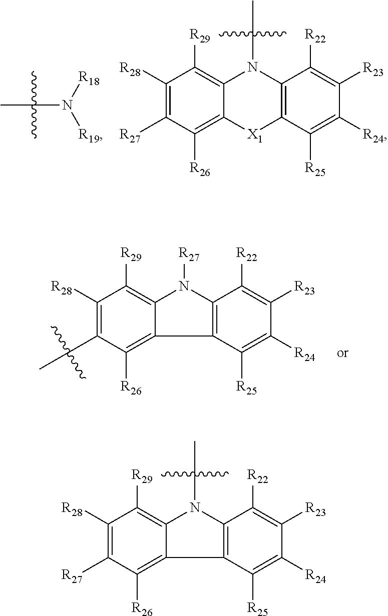
where R₁₈-R₁₉ are independently hydrogen, unsubstituted alkyl, substituted alkyl, unsubstituted cycloalkyl, substituted cycloalkyl, unsubstituted aryl, substituted aryl, acyl, unsubstituted aralkyl, unsubstituted aralkyl, styryl, aryloxycarbonyl, phenoxycarbonyl, or an alkoxycarbonyl group, where a pair of adjacent R groups of R₁₈-R₁₉ can independently form a 5-8 member heterocyclic ring; and R₂₂-R₂₉ are independently hydrogen, halogen, hydroxyl, an unsubstituted alkyl, a substituted alkyl, cycloalkyl, unsubstituted aryl, substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, or alkoxycarbonyl and X₁ is selected from CH₂, CHR, CR₂, O, S, NH, NR, PR, or SiR₂, and where R is independently hydrogen, unsubstituted alkyl, a substituted alkyl, cycloalkyl, unsubstituted aryl, substituted aryl, acyl, unsubstituted aralkyl, substituted aralkyl, or styryl; and
where R₂-R₉ are independently hydrogen, halogen, hydroxyl, unsubstituted alkyl, substituted alkyl, cycloalkyl, unsubstituted aryl, substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, or alkoxycarbonyl, and where any pair of adjacent R groups or substituents on the spacers separated by three or four bonds can form portions of a substituted or unsubstituted 5-8 member cycloalkyl, aryl, heterocycle, or heteroaryl ring,

8. The tetradentate ligand according to claim 7, wherein the chemical structure is: 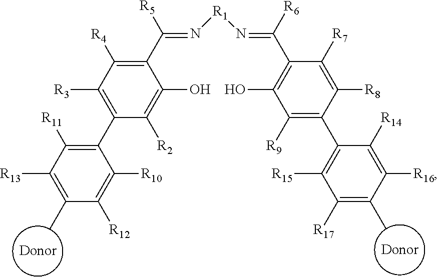
where R₁₁-R₁₇ are independently hydrogen, halogen, hydroxyl, an unsubstituted alkyl, a substituted alkyl, cycloalkyl, an unsubstituted aryl, a substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, or alkoxycarbonyl, and, optionally, one or more of R₁₁ and R₁₃, R₁₀ and R₁₂, R₁₄ and R₁₆, R₁₅ and R₁₇, and when donors are 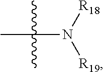
R₁₃ and R₁₈, R₁₂ and R₁₈, R₁₆ and R₁₈, R₁₇ and R₁₈ in combination is a portion of a 5-8 member ring.

9. The tetradentate ligand according to claim 7, selected from:

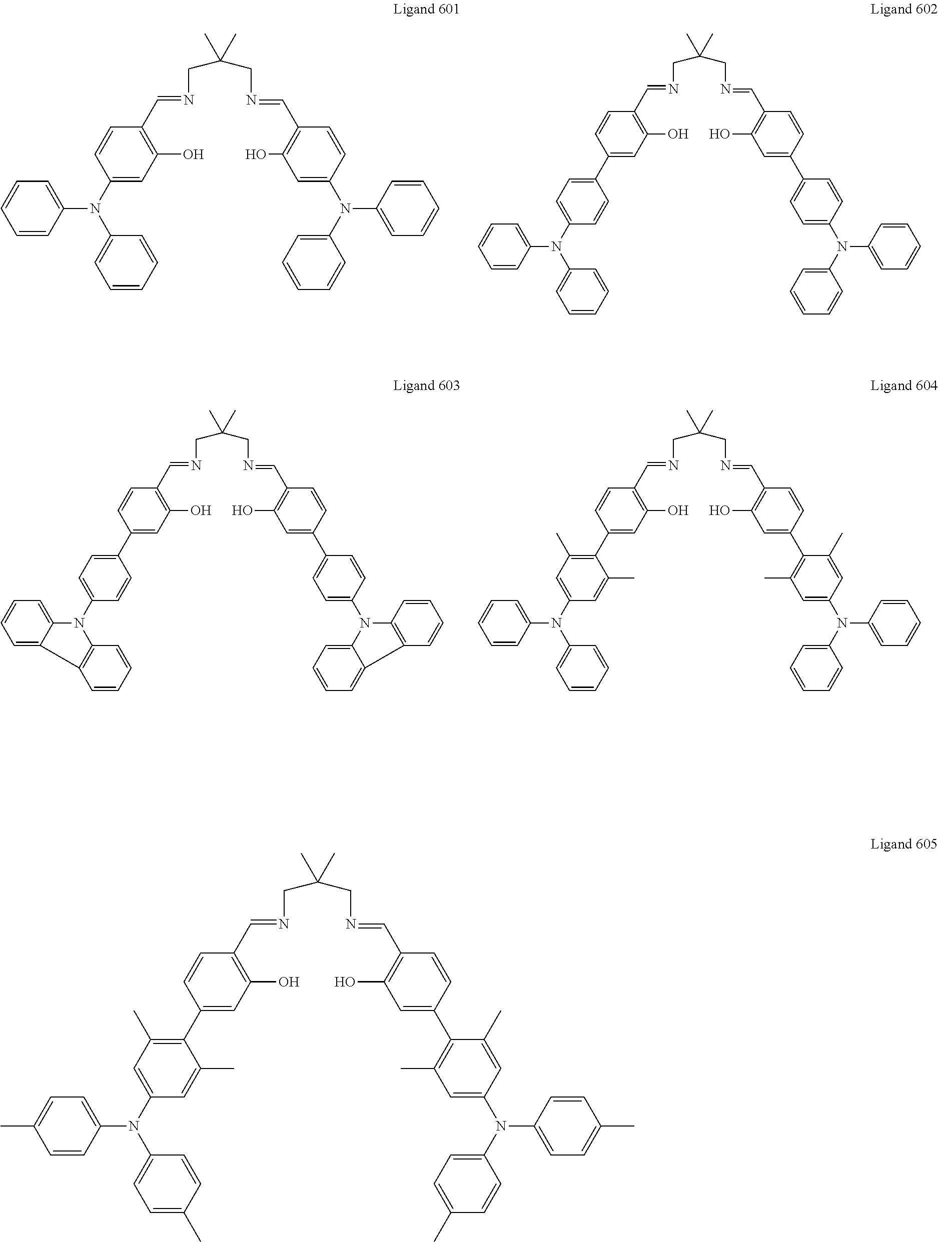

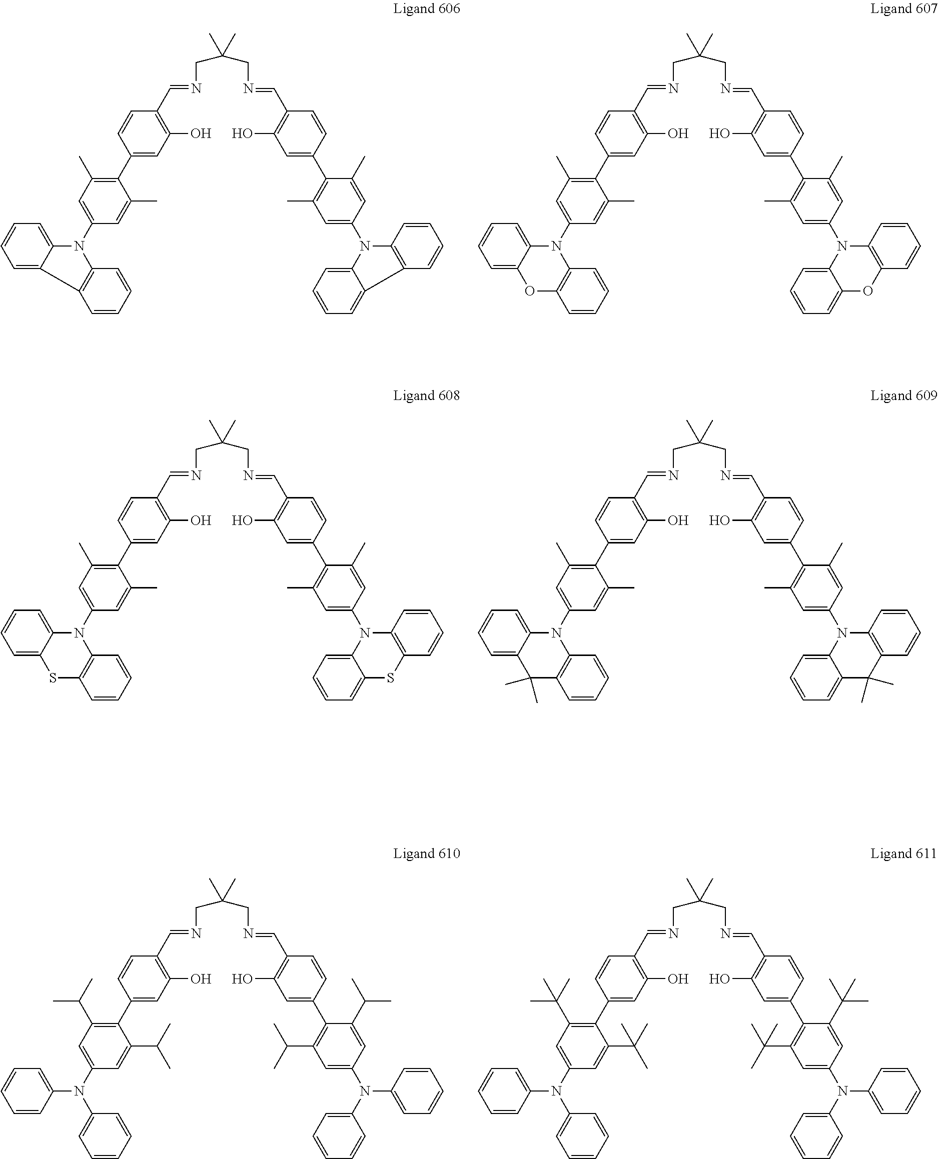

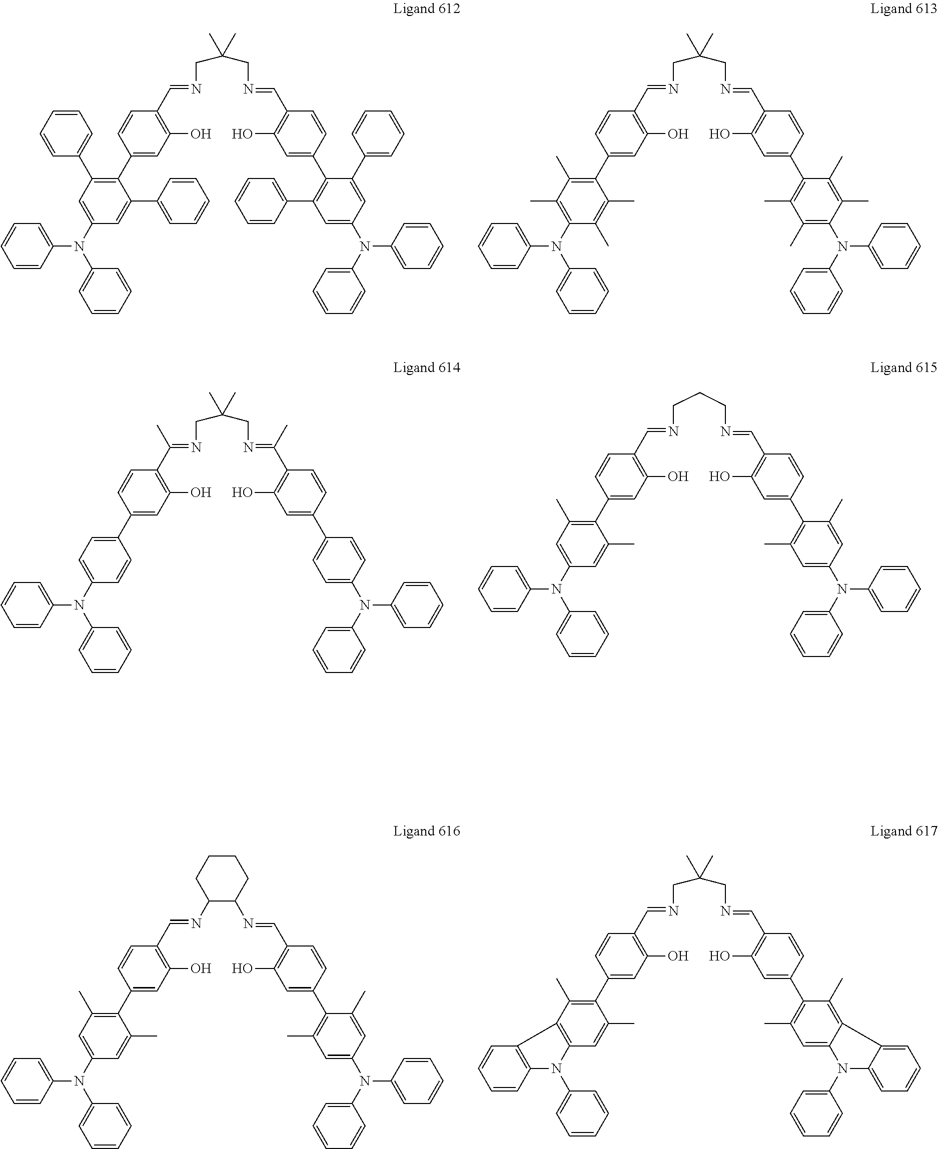

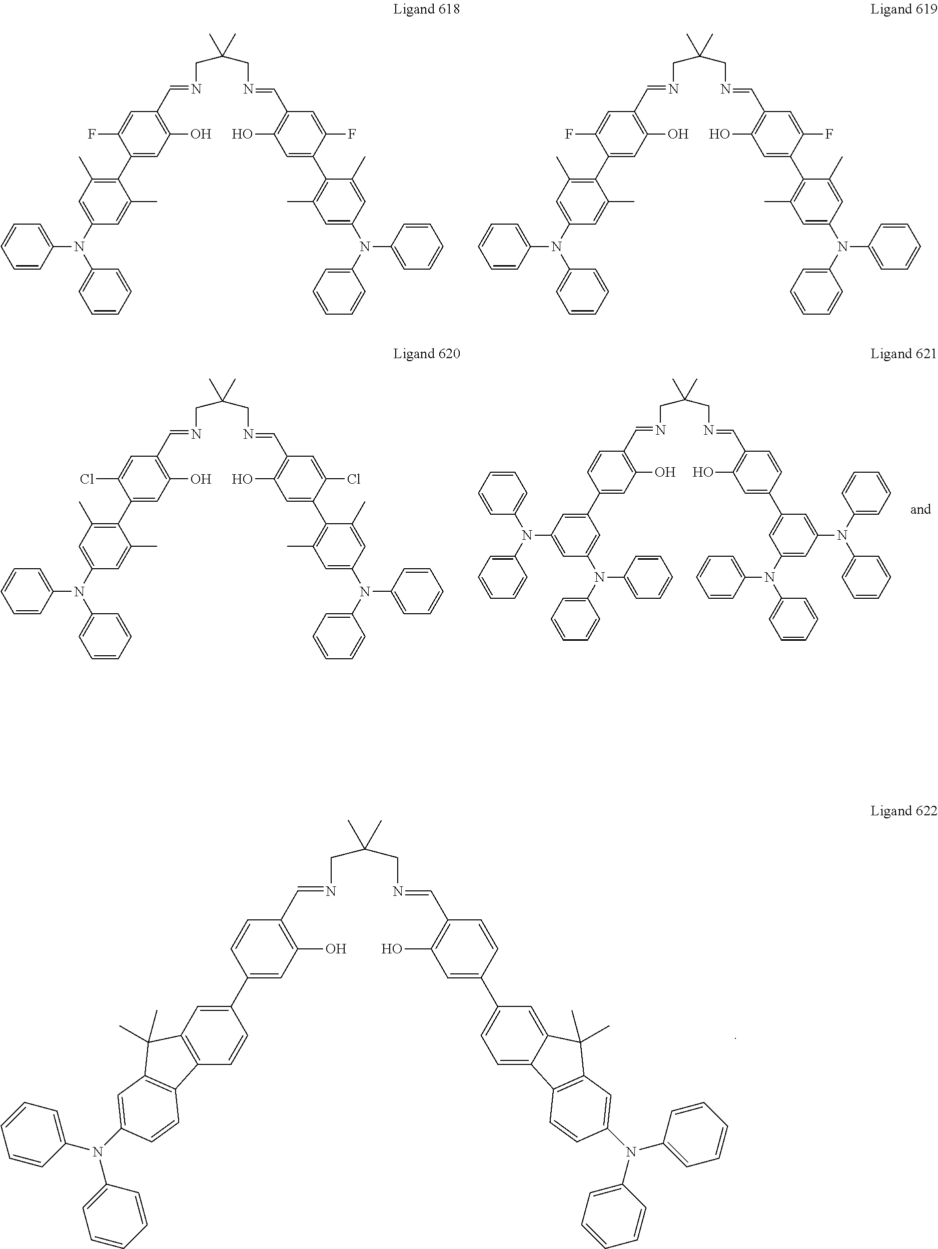

10. An electronic device, comprising at least one compound according to claim 1.

11. The electronic device according to claim 10, wherein the device is an organic light-emitting diode.

12. The electronic device according to claim 10, wherein the compound is at a concentration of more than 4 weight percent.

13. An electronic device containing one or more emissive layers, wherein each of the emissive layers comprises at least one compound according to claim 1.

14. An electronic device comprising at least one compound according to claim 1, wherein the at least one compound according to claim 1 resides in an electron transport layer, a hole blocking layer, or an emitting layer.

15. An electronic device comprising at least one compound according to claim 1 and further comprising a doping agent, wherein the at least one compound according to claim 1 comprises a host material for the doping agent.

16. The electronic device according to claim 10, wherein the electronic device is an electrophotographic photoreceptor, a photoelectric converter, an organic solar cell, a switching element, an organic light emitting field effect transistor, an image sensor, a dye laser, or an electroluminescent device.

17. The electronic device according to claim 10, wherein the electronic device is a stationary visual display unit, a mobile visual display unit, a illumination unit, a keyboard, an article of clothing, furniture, or wallpaper.

18. A method of preparing a compound having the following structure: 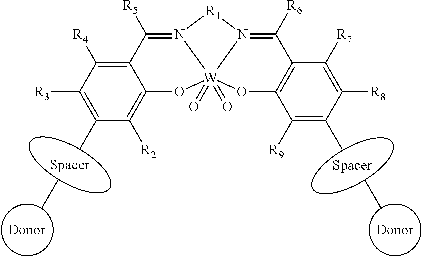
where:
W is tungsten in an oxidation state of VI;
R₁ is a connector between imine (C═N) units selected from a single bond or a bridge comprising a plurality of atoms and bonds, optionally containing heteratoms selected from —O—, and —S—, substituted or unsubstituted C₁-C₆ alkylene, substituted or unsubstituted C₃-C₁₂ cycloalkylene, C₂-C₈ alkenylene, substituted or unsubstituted C₆-C₁₀ arylene, sulfonyl, carbonyl, —CH(OH)—, —C(═O)O—,—O—C(═O)—, or 5-8 member heterocyclene group, or any combination of two or more of these groups; preferably, R₁ is a connector between imine (C═N) units selected from substituted or unsubstituted C₁-C₆ alkylene, and substituted or unsubstituted C₃-C₁₂ cycloalkylene.
spacers are independently selected from a single bond, unsubstituted or substituted C₆-C₁₀ arylene or C₆-C₁₀ heteroarylene; preferably, spacers are independently selected from a single bond, and unsubstituted or substituted C₆-C₁₀ arylene; and
donors are independently selected from one or two of the following structures: 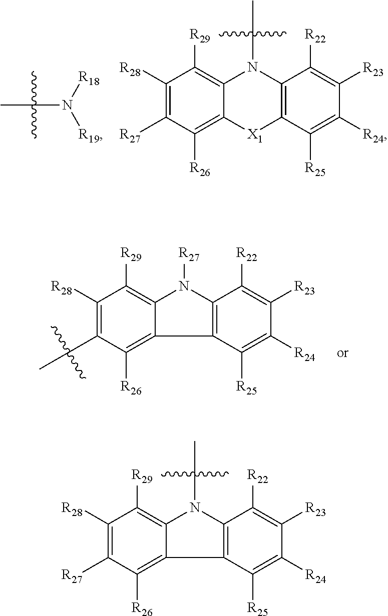
where R₁₈-R₁₉ are independently hydrogen, unsubstituted alkyl, substituted alkyl, unsubstituted cycloalkyl, substituted cycloalkyl, unsubstituted aryl, substituted aryl, acyl, unsubstituted aralkyl, unsubstituted aralkyl, styryl, aryloxycarbonyl, phenoxycarbonyl, or an alkoxycarbonyl group, where a pair of adjacent R groups of R₁₈-R₁₉ can independently form a 5-8 member heterocyclic ring; and R₂₂-R₂₉ are independently hydrogen, halogen, hydroxyl, an unsubstituted alkyl, a substituted alkyl, cycloalkyl, unsubstituted aryl, substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, or alkoxycarbonyl and X₁ is selected from CH₂, CHR, CR₂, O, S, NH, NR, PR, or SiR₂, and where R is independently hydrogen, unsubstituted alkyl, a substituted alkyl, cycloalkyl, unsubstituted aryl, substituted aryl, acyl, unsubstituted aralkyl, substituted aralkyl, or styryl;
preferably, donors are independently selected from one or two of the following structures: 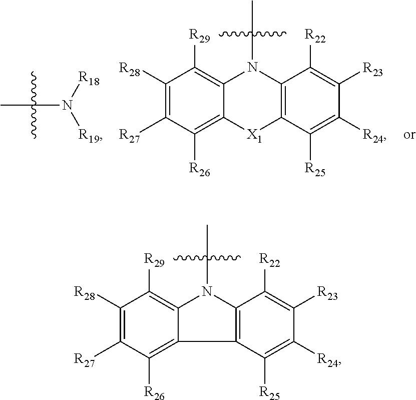
where R₁₈-R₁₉ are independently unsubstituted aryl, or substituted aryl, where a pair of adjacent R groups of R₁₈-R₁₉ can independently form a 5-8 member heterocyclic ring; and R₂₂-R₂₉ are independently hydrogen, an unsubstituted alkyl, or a substituted alkyl, and unsubstituted aryl, substituted aryl, and X₁ is selected from CH₂, CHR, CR₂, O, or S, and where R is independently unsubstituted alkyl, or a substituted alkyl; and
where R₂-R₉ are independently hydrogen, halogen, hydroxyl, unsubstituted alkyl, substituted alkyl, cycloalkyl, unsubstituted aryl, substituted aryl, acyl, alkoxy, acyloxy, amino, nitro, acylamino, aralkyl, cyano, carboxyl, thio, styryl, aminocarbonyl, carbamoyl, aryloxycarbonyl, phenoxycarbonyl, or alkoxycarbonyl, and where any pair of adjacent R groups or substituents on the spacers separated by three or four bonds can form portions of a substituted or unsubstituted 5-8 member cycloalkyl, aryl, heterocycle, or heteroaryl ring; preferably, R₂-R₉ are independently hydrogen, or halogen,
the method, comprising:
providing a tetradentate ligand according to claim 7;
providing a tungsten(VI) salt; and
mixing the tetradentate ligand with the tungsten(VI) salt in a solvent.

19. The method according to claim 18, wherein the tungsten(VI) salt is a tungsten(VI) ethylene diamine complex (W(VI)(eg)₃).

20. The method according to claim 18, wherein the solvent is an alcohol.

21. The method according to claim 20, wherein the alcohol is methanol.

22. The method according to claim 18, wherein providing the tetradentate ligand comprises:
providing a donor comprising or donor and spacer comprising boronate ester intermediate;
reacting the boronate ester intermediate with an unsubstituted or substituted 4-bromo-2-hydroxybenzaldehyde or an unsubstituted or substituted 4-bromo-2-hydroxybenzyl ketone to form a dicarbonyl intermediate; and
reacting the dicarbonyl intermediate with a diamine comprising compound to form the tetradentate ligand.

23. The method according to claim 22, wherein reacting the boronate ester intermediate comprises a Suzuki coupling with a Pd comprising catalyst.
